(19) United States
(12) Patent Application Publication
(10) Pub. No.: US 2026/0082492 A1
(43) Pub. Date: Mar. 19, 2026

(54) ELECTRONIC DEVICE WITH STRENGTHENED FOLDABLE COVER

(71) Applicant: Apple Inc., Cupertino, CA (US)

(72) Inventors: Christopher D. Jones, Los Altos, CA (US); Gerd Brandstetter, Sunnyvale, CA (US)

(21) Appl. No.: 19/315,625

(22) Filed: Aug. 31, 2025

Related U.S. Application Data
(60) Provisional application No. 63/696,810, filed on Sep. 19, 2024.

(51) Int. Cl. H05K 5/02; H05K 5/00; H05K 5/03

(52) U.S. Cl. CPC H05K 5/0226; H05K 5/0018; H05K 5/03

(57) ABSTRACT

A strengthened foldable cover may include a cover member formed from a glass material. A hinge of the cover member defines a bend in the folded configuration of the foldable cover. One or more portions of the cover member that define the hinge may be strengthened differently than other portions of the cover member in order to facilitate bending of the cover member while providing damage resistance and minimizing distortion of graphical output from the display assembly.

### CROSS-REFERENCE TO RELATED APPLICATION(S)

This application is a nonprovisional application of and claims the benefit of U.S. Provisional Patent Application No. 63/696,810, filed Sep. 19, 2024, and titled “Electronic Device With Strengthened Foldable Cover,” the disclosure of which is hereby incorporated herein by reference in its entirety.

### FIELD

The described embodiments relate generally to electronic devices with a foldable or flexible cover. More particularly, the present embodiments relate to foldable covers that are strengthened to provide damage resistance to the cover and that are coupled to a flexible display assembly.

### BACKGROUND

Some traditional electronic devices include a cover to protect an underlying display. When the display is positioned within an enclosure that has a single form factor, the cover may include a glass member having a thickness sufficient to provide rigidity to the cover member.

Embodiments described herein are directed to portable electronic device including a foldable cover coupled to a flexible display.

### SUMMARY

Aspects of the following disclosure relate to foldable electronic devices. In some embodiments, the electronic device includes a foldable cover positioned over a display assembly. The foldable cover defines a hinge structure that allows the foldable cover to move between an unfolded configuration and a folded configuration. The foldable cover may be coupled to a foldable housing and the display assembly may be a flexible display assembly. Enclosures including the foldable cover, foldable covers, and foldable cover members are also disclosed herein.

In embodiments described herein, the hinge structure of the foldable cover is transparent and positioned between first and second windows of the foldable cover. The foldable cover is positioned over the display assembly so that graphical output from the display assembly may be viewed through the hinge structure and both windows. The foldable cover includes a cover member that defines a hinge. The hinge defines a bend in a folded configuration of the foldable cover.

In some embodiments, the hinge of the cover member is formed from a glass material. The hinge may be thin to limit the extent of bending induced tensile stresses in the folded configuration of the cover member. In some examples described herein, the hinge has a thickness that is about the same as the thickness of these other portions of the cover member. In other examples, a thickness of the hinge is less than a thickness of other portions of the cover member to facilitate bending of the hinge.

The cover member may be strengthened at least in part through ion exchange. The strengthening of the cover member may provide a balance between facilitating bending of the cover member, providing damage resistance to the cover member, and, in some cases, minimizing distortion of graphical output from the display assembly. In embodiments described herein, one or more portions of the cover member that define the hinge may be strengthened differently than other portions of the cover member in order to provide the desired balance between these factors. In some cases, one or more portions of the cover member may be strengthened through dual ion exchange.

The disclosure provides an electronic device comprising a display assembly, a housing at least partially enclosing the display assembly, and a cover coupled to the housing and defining a first window positioned over a first portion of the display assembly, a second window positioned over a second portion of the display assembly, and a hinge structure positioned between the first and the second windows, the cover including a cover member formed from a glass material and comprising a first portion at least partially defining the first window and having a first thickness and a first stress pattern defining a first compressive region depth and a first in-plane expansion value, a second portion at least partially defining the second window and having a second thickness and a second stress pattern defining a second compressive region depth and a second in-plane expansion value, and a hinge portion positioned between the first and the second portions and at least partially defining the hinge structure, an unfolded configuration of the hinge portion having a third thickness that is less than a thickness of each of the first thickness and the second thickness and a third stress pattern that is different from each of the first and the second stress patterns, the third stress pattern defining a third compressive region depth that is greater than zero and less than each of the first compressive region depth and the second compressive region depth and a third in-plane expansion value that is matched to each of the first in-plane expansion value and the second in-plane expansion value.

The disclosure also provides an electronic device comprising a display assembly comprising a first active display area, a second active display area, and a third active display area, a housing at least partially enclosing the display assembly, and a cover coupled to the housing and comprising a cover member formed from a glass material and configured to move between a folded configuration and an unfolded configuration, the cover member comprising a first portion positioned over the first active display area and defining a first thickness and a first stress pattern having a first surface compressive stress and a first compressive region depth at an interior surface of the cover member, a second portion positioned over the second active display area and defining a second thickness and a second stress pattern having a second surface compressive stress and a second compressive region depth at the interior surface, and a third portion positioned between the first portion and the second portion and over the third active display area, the third portion defining a bend in the folded configuration of the cover member and defining, in the unfolded configuration of the cover member, a third thickness that is less than each of the first thickness and the second thickness, and a third stress pattern that is different from each of the first and the second stress patterns, the third stress pattern having a third compressive region depth that is less than or equal to each of the first compressive region depth and the second compressive region depth at the interior surface and a third surface compressive stress that is greater than or equal to each of the first surface compressive stress and the second surface compressive stress at the interior surface of the cover member . . . .

The disclosure also provides an electronic device comprising a display assembly comprising a touch-sensitive layer, a housing at least partially enclosing the display assembly, and a cover coupled to the housing and positioned over the display assembly, the cover including a cover member comprising a first portion positioned over a first portion of the display assembly, the first portion of the cover member having a first thickness and a first rear ion-exchanged layer having a first depth, a second portion positioned over a second portion of the display assembly, the second portion of the cover member having a second thickness and a second rear ion-exchanged layer having a second depth, a third portion positioned between the first and the second portions and over a third portion of the display assembly, the third portion of the cover member having a third thickness less than each of the first and the second thicknesses and a third rear ion-exchanged layer having a third depth less than each of the first depth of the first rear ion-exchanged layer and the second depth of the second rear ion-exchanged layer, a first intermediate portion positioned between the third portion and the first portion and defining a fourth rear ion-exchanged layer and a second intermediate portion positioned between the third portion and the second portion and defining a fifth rear ion-exchanged layer.

### BRIEF DESCRIPTION OF THE DRAWINGS

The disclosure will be readily understood by the following detailed description in conjunction with the accompanying drawings, wherein like reference numerals designate like elements.

FIG. 1 shows an electronic device in an unfolded configuration.

FIG. 2A shows a side view of an electronic device in a folded configuration.

FIG. 2B shows a side view of an electronic device in another folded configuration.

FIG. 3 shows a partial cross-sectional view of an electronic device.

FIG. 4A shows a magnified partial cross-sectional view of an electronic device.

FIG. 4B shows another magnified partial cross-sectional view of an electronic device.

FIG. 5 shows another partial cross-sectional view of an electronic device.

FIG. 6 shows a magnified top view of a cover member for an electronic device.

FIG. 7 shows an example of a partial cross-sectional view of a cover member.

FIG. 8 shows an example of a cover member in a folded configuration.

FIG. 9 shows an example view of a strengthened cover member.

FIG. 10 shows an example partial cross-sectional view of a strengthened cover member.

FIG. 11 shows another example partial cross-sectional view of a strengthened cover member.

FIG. 12 shows another example partial cross-sectional view of a strengthened cover member.

FIG. 13 shows another example partial cross-sectional view of a strengthened cover member.

FIG. 14A shows an example of compressive stress profiles as a function of distance in a hinge defined by a strengthened cover member.

FIG. 14B shows an example of ion concentration as a function of distance in a hinge defined by a strengthened cover member.

FIG. 15A shows an example of compressive stress profiles as a function of distance at a location outside the hinge of a strengthened cover member.

FIG. 15B shows an example of ion concentration as a function of distance at a location outside the hinge of a strengthened cover member.

FIG. 15C shows another example of ion concentration as a function of distance at a location outside the hinge of a strengthened cover member.

FIG. 16 shows another example of a strengthened cover member defining a hinge.

FIG. 17 shows another cross-sectional view of a strengthened cover member.

FIG. 18 shows another example of a compressive stress profile at a location outside the hinge.

FIG. 19 shows examples of ion concentration profiles within a compressive region of a strengthened cover member.

FIG. 20 shows an example block diagram of components of an electronic device.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred implementation. To the contrary, the described embodiments are intended to cover alternatives, modifications, and equivalents as can be included within the spirit and scope of the disclosure and as defined by the appended claims.

The following disclosure relates to foldable electronic devices. In some embodiments, the electronic device includes a foldable cover positioned over a flexible display assembly and coupled to a housing. The housing may include a multipart mechanical hinge, but the cover may lack such a hinge. Enclosures including the foldable cover, foldable covers, and foldable cover members are also disclosed herein. Foldable covers and cover members may alternately be referred to herein as bendable or flexible covers and cover members.

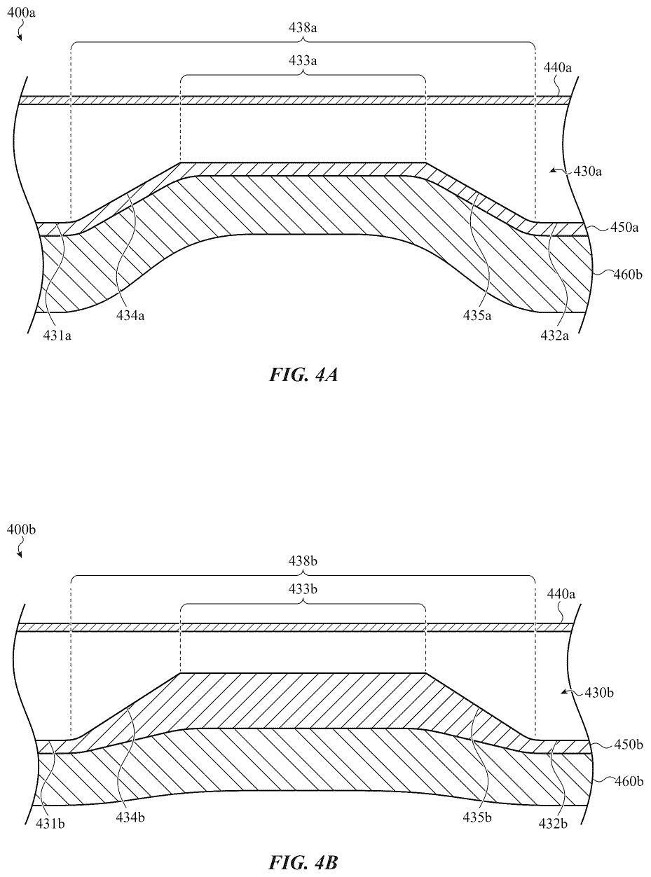

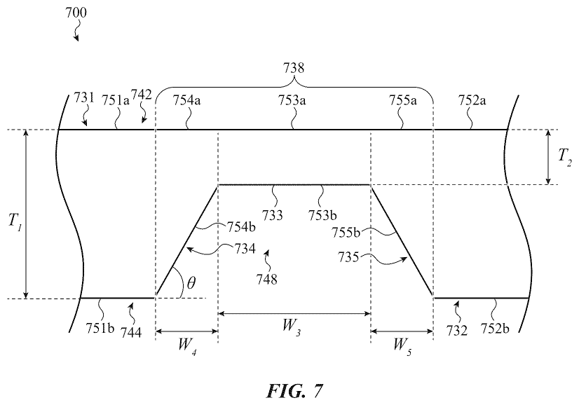

The foldable cover member includes a cover member that defines a hinge. The hinge defines a bend in a folded configuration of the foldable cover. In some embodiments, the hinge may be integrally formed with other portions of the cover member. For example, the cover member may be formed from a single piece of material. The cover member, including the hinge, may be formed from a glass material or another material having a relatively high modulus. In some embodiments, the cover member is formed from an ion-exchangeable material that is capable of dual ion exchange. The description of ion-exchangeable cover member compositions provided with respect to FIGS. 3 and 7 is generally applicable herein and is not repeated here. The hinge of the cover member may alternately be referred to herein as a hinge portion of the cover member.

The hinge may be thin to limit the extent of bending induced tensile stresses in the folded configuration of the cover member. In some embodiments, a thickness of the hinge is less than a thickness of other portions of the cover member to facilitate bending of the hinge during movement of the cover member from an unfolded configuration to a folded configuration. For example, a thickness of the hinge may be less than a thickness of the portions of the cover member that define the first and second windows of the cover. In other embodiments, the hinge may have a thickness that is about the same as these other portions of the cover member. The examples of cover member thicknesses provided with respect to FIG. 3 is generally applicable herein and is not repeated here.

In embodiments described herein, one or more portions of the cover member that define the hinge may be strengthened differently than other portions of the cover member, as discussed in more detail below. The use of different stress patterns in different portions of the cover member can help to provide a balance between facilitating bending of the cover member, providing damage resistance to the cover member, and, in some cases, minimizing distortion of graphical output from the display assembly. In some embodiments, a stress pattern of a portion of the cover member within the hinge has a higher level of compressive stress at and near a surface of the cover member and a shallower compressive region depth as compared to the stress pattern of another portion of the cover member that is positioned outside the hinge. In some examples, the stress pattern may be determined along a thickness of the cover member. In some cases, one or more portions of the cover member within the hinge are strengthened through single ion exchange while other portions of the cover member are strengthened through dual ion exchange, as described in more detail below.

In embodiments described herein, strengthening of the cover member may be configured to minimize distortion of graphical output from the display assembly by minimizing some forms of shape change within the hinge. As an example, the strengthening of the cover member may be configured to minimize undesirable shape change within a hinge, such as an unacceptable deviation from planarity of one or more surfaces of the hinge in an unfolded configuration of the cover.

Inclusion of a strengthened cover member in the foldable cover provides a strengthened foldable cover capable of defining a relatively small bend radius while having resistance to damage. In some cases, the strengthened foldable cover also includes a coating disposed on an exterior surface of the cover member that further increase the damage resistance of the foldable cover. In some embodiments, the strengthened foldable cover also minimizes distortion of graphical output from the display. In some examples, the bend radius of an electronic device including the strengthened foldable cover may be in a range from 1 mm to 10 mm, from 5 mm to 10 mm, from 2 mm to 7 mm, or from 1 mm to 5 mm.

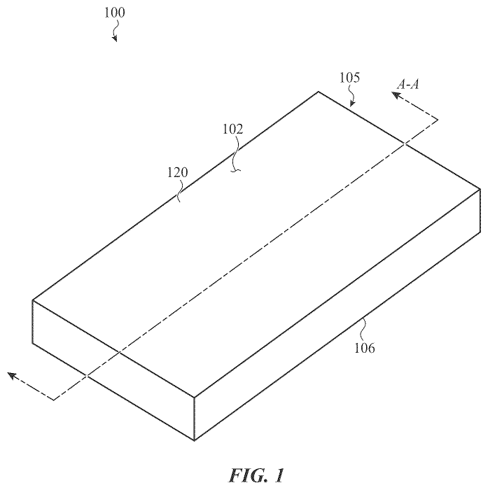

These and other embodiments are discussed below with reference to FIGS. 1-20. However, those skilled in the art will readily appreciate that the detailed description given herein with respect to these figures is for explanatory purposes only and should not be construed as limiting.

FIG. 1 shows an electronic device in an unfolded configuration. The electronic device 100 may be a mobile telephone (also referred to as a mobile phone). In other examples, the electronic device may have the form of a tablet computer, a laptop computer, a display monitor, a wearable electronic device (e.g., a smart watch or a headset), or another form of electronic device.

The electronic device 100 includes an enclosure 105. The enclosure 105 includes a housing 110 and a cover 120 coupled to the housing 110. The cover 120 may be positioned over a display assembly (e.g., the display assembly 360 of FIG. 3) and defines at least a portion of a front surface 102 of the electronic device 100. In some embodiments, a front surface of an electronic device is a surface of the device that typically faces a user when the electronic device is an unfolded configuration. The housing 110 defines at least a portion of a side surface 106 of the electronic device 100. The cover 120, the display assembly 140, and the housing 110 may be similar to the cover 320, the display assembly 360, and the housing 310 described with respect to FIG. 3 and that description is generally applicable herein.

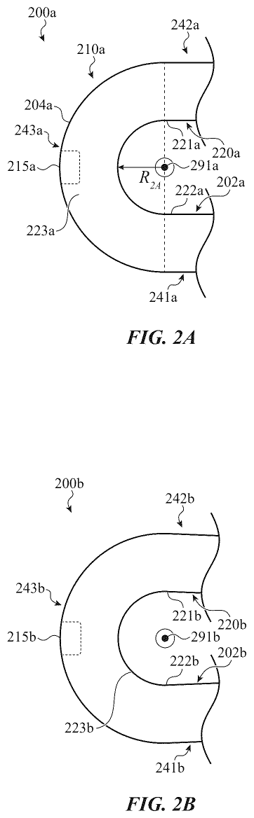

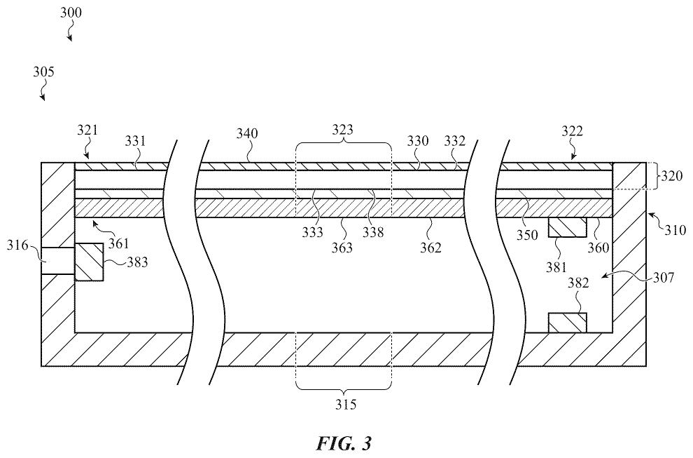

FIG. 2A shows a side view of an electronic device in a folded configuration. In the example of FIG. 2A, the electronic device 200a is bent around a bend axis 291a and each of the cover 220a and the housing 210a defines a respective folded configuration. The electronic device 200a defines a bend 243a and first and second portions 241a, 242a positioned away from the bend. A rear surface 204a of the electronic device 200a defines an outside of the bend 243a and a front surface 202a of the electronic device 200a defines an inside of the bend 243a. In some embodiments, the housing 210a and/or a rear cover of the housing 210a may include a mechanical hinge component 215a having a multipart construction (e.g., a mechanical hinge component with separate components that rotate with respect to each other).

In embodiments described herein, the cover 220a lacks a mechanical hinge component. Instead, the cover 220a includes a cover member that defines a hinge, as shown in the cross-sectional view of FIG. 3. The cover 220a of the electronic device defines a bend region 223a and the hinge structure defined by the cover member is positioned within the bend region 223a. The boundaries of the bend region (and, in some cases, the hinge structure) are indicated with dashed lines in FIG. 2A.

The cover 220a also includes windows 221a and 222a, which are contiguous with the bend region 223a. The windows 221a and 222a may be positioned over active display areas of the display assembly. In the folded configuration of the cover, the windows 221a and 222a (alternately, window regions) overlap one another and the bend region 223a defines a bend radius R_{2A}. In some embodiments, the bend radius may be in a range from 1 mm to 10 mm, from 5 mm to 10 mm, from 2 mm to 7 mm, or from 1 mm to 5 mm.

The bend region 223a of the cover also defines a bend angle. As shown in FIG. 2A, the cover 220a may define a bend angle of about 180 degrees in a folded configuration of the electronic device. A spacing between the windows 221a and 222a of the cover 220a may therefore define a parallel plate spacing. In some embodiments, the parallel plate spacing in the folded configuration of the cover is approximately twice the bend radius.

FIG. 2B shows a side view of an electronic device in another folded configuration. In some examples an electronic device may have more than one folded configuration. The electronic device 200b defines a bend 243b and first and second portions 241b, 242b positioned away from the bend. The bend axis 291b is also shown in FIG. 2B. As shown in FIG. 2B, the cover 220b defines a bend region 223b which may define a bend angle greater than 180 degrees in the folded configuration of the electronic device 200b. In these embodiments, the ends of the electronic device 200b may be separated by a spacing that is less than the parallel plate spacing. In some cases, the ends of the electronic device 200b may contact each other. The windows 221b, 222b, and bend region 223b of the cover 220b may be similar to the windows 221a, 222a, and the bend region 223a, the housing 210b may be similar to the housing 210a, and the hinge component 215b may be similar to the hinge component 215a and that description is not repeated here.

FIG. 3 shows a partial cross-sectional view of an electronic device. The electronic device 300 includes a foldable cover 320 positioned over a display assembly 360. The foldable cover 320 is coupled to a housing 310. As previously discussed with respect to FIG. 2A, the housing 310 may include a mechanical hinge component 315, but the foldable cover 320 may lack such a mechanical hinge component. Although FIG. 3 shows the electronic device 300 in an unfolded configuration, each of the electronic device 300, the foldable cover 320, the cover member 330 and the housing 310 are configured to move between the unfolded configuration and at least one folded configuration. The electronic device 300 may be an example of the device 100 and the cross-section may be taken along A-A in FIG. 1.

As shown in FIG. 3, the foldable cover 320 defines a first window 321, a second window 322, and a hinge structure 323. The hinge structure 323 is defined at least in part by a cover member 330, as described in more detail below. The first window 321 is positioned over a first portion 361 of the display assembly 360 and the second window 322 is positioned over a second portion 362 of the display assembly. The hinge structure 323 may be positioned over a third portion 363 of the display assembly. In some examples, the foldable cover 320 defines a single hinge structure 323 that is centrally located along the width or the length of the electronic device 300. However, these examples are not intended to be limiting and more generally a foldable cover may include one or more hinge structures positioned to provide the desired folded configuration(s) of the electronic device.

The foldable cover 320 includes a cover member 330 that defines a hinge 338 positioned within the hinge structure 323. In some embodiments, the cover member 330 is formed of a transparent material, such as a glass material, a glass ceramic material, or the like. The glass material may be an ion-exchangeable silicate glass material, such as an alkali aluminosilicate glass material. In some cases, the ion-exchangeable silicate glass material may be capable of dual ion exchange. The transparent material may be other than a polymeric material. The cover member may be formed from a single piece of material rather than from an assembly of layers. Typically, the cover member 330 is formed from a material that has a relatively high Young's modulus in order to provide resistance to scratching and/or puncture of the cover member 330.

The cover member 330 includes a first portion 331 and a second portion 332 and the hinge 338 is defined at least in part by a third portion 333 of the cover member that is positioned between the first and the second portions 331 and 332. The hinge 338 may alternately be referred to herein as a hinge portion of the cover member 330. The hinge may be integrally formed with other portions of the cover member.

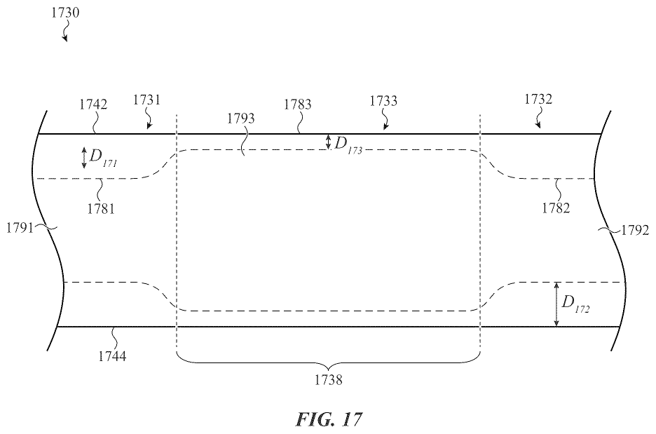

In some embodiments, the hinge 338 may have a thickness that is about the same as the first portion 331 and the second portion 332 of the cover member, as shown at least in the magnified view of FIG. 17. The thickness of the third portion 333 of the member may be thin to facilitate bending of the hinge 338 and in some cases may be in a range from 20 micrometers to 120 micrometers. In some examples, the first portion 331, the second portion 332, and the third portion 333 each have a thickness in a range from 20 micrometers to 50 micrometers. In other examples, the first portion 331, the second portion 332, and the third portion 333 each have a thickness in a range from 50 micrometers to 100 micrometers.

In other embodiments described herein, the third portion 333 of the cover member has a thickness that is less than a thickness of each of the first portion 331 and the second portion 332, as shown at least in the magnified views of FIGS. 4A, 4B, and 7. The lesser thickness of the third portion 333 of the cover member 330 can reduce the level of maximum bending-induced tensile stress at the outside of the bend when the cover member 330 is in a folded configuration. In some embodiments, the outside of the bend in the cover member will be at the interior surface of the third portion of the cover member 330 (facing the display assembly 360). In some cases, the thickness of the third portion 333 of the cover member 330 is in a range from 20 micrometers to 120 micrometers. In some examples, the third portion 333 of the cover member 330 has a thickness in a range from 20 micrometers to 50 micrometers and each of the first and the second portions 331, 332 of the cover member 330 has a thickness that is greater than a thickness of the third portion 333 of the cover member and that is in a range from 60 micrometers to 200 micrometers. In some examples, the third portion 333 of the cover member 330 has a thickness in a range from 50 micrometers to 100 micrometers and each of the first and the second portions 331, 332 of the cover member 330 has a thickness that is greater than a thickness of the third portion 333 of the cover member and that is in a range from 150 micrometers to 400 micrometers.

In some embodiments, the hinge 338 is further defined by additional portions of the cover member (e.g., intermediate portions) which provide a thickness transition between the third portion 333 and each of the first portion 331 and the second portion 332. Examples of cross-sectional views of cover members defining hinges including intermediate portions are shown at least in FIGS. 4A, 4B, and 7 and the description provided with respect to these figures is generally applicable herein.

The windows 321 and 322 of the cover 320 are also defined at least in part by portions of the cover member. The first window 321 of the cover 320 is defined at least in part by a first portion 331 of the cover member 330, and the second window 322 is defined at least in part by a second portion 332 of the cover.

The cover member 330 may be strengthened at least in part through ion exchange. The strengthening of the cover member 330 may provide a balance between facilitating bending of the cover member, providing damage resistance, and, in some cases, minimizing distortion of graphical output from the display due to shapes changes in the cover member. In embodiments described herein, the one or more portions of the cover member defining the hinge (e.g., the third portion 333) may be strengthened differently than other portions of the cover member (e.g., the first and second portions 331 and 332).

In some embodiments, the portion(s) of the cover member within the hinge (e.g., the third portion 333) may be strengthened to have a stress pattern that has relatively high levels of compressive stress at and near a surface to help counteract bending-induced tensile stress but has a limited compressive region depth. Limiting the depth of the compressive region within the hinge may help to maintain the relatively high levels of compressive stress at or near the surface (e.g., by limiting relaxation of compressive stress within the hinge). Alternately or additionally, limiting the depth of the compressive region within the hinge may help avoid undue levels of tensile stress within the hinge.

In some embodiments, portions of the cover member that are positioned outside the hinge (e.g., the first and the second portions 331, 332) may be strengthened to have a stress pattern that has a greater compressive region depth and that may have other differences from the stress pattern in the hinge. For example, the stress pattern in portions of the cover member that are positioned outside the hinge may have one or more of a lower maximum tensile stress within the interior of the cover member, a lower compressive stress at the surface of the cover member, or a lower maximum compressive stress. A greater depth of the compressive region in the first and second portions 331 and 332 of the cover member 330 can help protect the window from damage such as formation of a scratch and/or crack. However, the maximum tensile stress within the interior of the cover member and, in some cases, the in-plane expansion due to ion exchange, may help determine the stress pattern in the first and second portions 331 and 332 of the cover member 330.

In the example of FIG. 3, the foldable cover 320 also includes a coating 340 disposed over an exterior surface of the cover member 330. In some embodiments, the coating 340 includes one or more of a polymer coating, an inorganic coating such as an anti-reflection coating or a hard coating, or an oleophobic coating. In some cases, the coating 340 is a multilayer coating that comprises multiple polymer layers and one or more inorganic layers that defines an exterior surface of the coating. The inorganic layer(s) may have a greater hardness than the polymer layers of the coating. In some cases, an inorganic layer may include or be formed of an oxide, a nitride, or an oxynitride material. As examples, the inorganic layer may be a silicon oxide layer, an aluminum oxide layer, a silicon nitride coating layer, a silicon oxynitride layer, or the like. The multilayer coating may be configured to have optical properties that do not substantially degrade the quality of graphical output from the display. For example, the multilayer coating 340 may be substantially transparent to visible light.

The device 300 includes a display assembly 360 that is coupled to the foldable cover 320. The display assembly 360 may include a touch-sensitive layer. In some embodiments, the display assembly is an organic light-emitting diode (OLED) display assembly or an active layer organic light-emitting diode (AMOLED) display assembly. In other embodiments, the display assembly is a liquid-crystal (LCD) assembly, a light-emitting diode (LED) display assembly, or an LED-backlit LCD display assembly. The display assembly 360 may have sufficient flexibility to bend with the foldable cover 320.

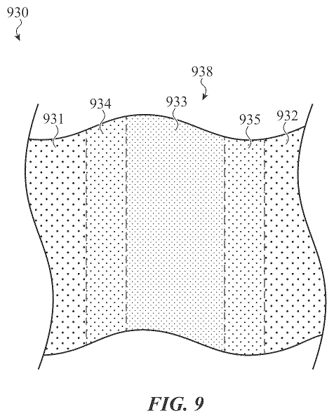

In some embodiments, the display assembly 360 is configured to provide graphical output that may viewed through any of the first portion 331, the second portion 332, and the third portion 333 of the cover member 330. As previously discussed, the hinge structure 323 of the cover 320 may be configured to minimize distortion of graphical output from the display assembly. For example, the chemical strengthening of the cover member 330 may be configured to minimize distortion of the graphical output due to shape changes in the cover member, as described in more detail at least with respect to FIGS. 7 and 9. The description provided with respect to FIGS. 7 and 9 is generally applicable herein.

The display assembly 360 is coupled to one or more portions of the cover member 330. As shown in the example of FIG. 3, the first portion 361 of display assembly 360 is positioned below and coupled to an interior surface of the first portion 331 of the cover member 330 while the second portion 362 of the display assembly 360 is positioned below and coupled to an interior surface of the second portion 332 of the cover member 330. The third portion 363 of the display assembly 360 may be positioned below and coupled to an interior surface of the hinge 338 defined by the cover member 330. The first portion 361 of the display assembly 360 may define a first active display area, the second portion 362 of the display assembly 360 may define a second active display area, and the third portion 363 of the display assembly 360 may define a third active display area.

In some embodiments, the different portions of the display assembly may be controlled separately and/or may provide different functions of the electronic device. In some cases, the display assembly may be configured to allow independent control of at least the first portion 361 and the second portion 362 of the display assembly 360. For example, a first active display area defined by the first portion 361 may be configured to display a keyboard in at least one mode of operation while the second active display area defined by the second portion 362 may display a different graphical output.

The touch-sensitive layer of the display assembly may be configured to allow independent control of different regions of the touch-sensitive layer. The first portion 361 of the display assembly 360 may include a first region of a touch-sensitive layer, the second portion 362 of the display assembly 360 may include a second region of the touch-sensitive layer, and the third portion 363 of the display assembly 360 may include a third region of the touch-sensitive layer. The touch-sensitive layer may be positioned over other layers of the display assembly that produce the graphical output. When the first active display area is configured to display a keyboard, a first region of the touch-sensitive layer may be configured to receive input to keys of the keyboard.

In embodiments, a coupling structure 350 couples the display assembly 360 to the foldable cover 320. The coupling structure 350 may also be configured to help limit stresses imposed on the display assembly during folding and unfolding of the electronic device 300. For example, the coupling structure 350 may be configured to allow for relative movement or shear between the display and cover member to reduce the bending stresses while folding the electronic device. In some embodiments, the coupling structure includes a set of layers and may be referred to as a multilayer coupling structure. One or more of the layers may be configured to allow relative movement or shear between the display and the cover member. The coupling structure may be optically matched to the cover member 330 to limit distortion of graphical output from the display assembly. For example, the refractive indices of the layers of the coupling structure may be about the same as the refractive index of the cover member. The set of layers may include a first layer formed from an optically clear adhesive (OCA) and a second layer formed of a material different from the first layer. In some embodiments, each layer of the set of layers is a polymer layer, so that the multilayer structure includes a set of polymer layers. In some cases, the coupling structure 350 may vary in thickness as shown in the example of FIG. 4B.

Each of the cover member 330, the coupling structure 350, and the coating 340 may be transparent to visible light. For example, each of the cover member 330, the coupling structure 350, and the coating 340 may have an average transmission for visible light that is at least 70%, at least 80%, or at least 85%. In some embodiments, the cover member 330 and the coating 340 may provide for transmission of other wavelengths of light, such as infrared (IR) light, in order to allow operation of an IR camera and/or an IR sensor through the cover member 330 and coating 340.

In some embodiments, the housing 310 may be formed from multiple members. For example, the housing 310 may include a set of conducting members, such as conducting members formed from one or more metals. Adjacent conducting members of the set of conducting members may be separated by a dielectric member of a set of dielectric members. The dielectric member can provide electrical isolation between adjacent conducting members. One or more of the conductive members may be coupled to internal circuitry of the electronic device and may function as an antenna for sending and receiving wireless communications. Alternately or additionally, the housing 310 may comprise a band that defines a side surface of the electronic device coupled to a multipart rear cover. As a non-limiting example, a multipart rear cover may define a central mechanical hinge coupling two rear cover members. Members of the housing may be formed from a conducting material such as a metal material, a dielectric material such as a polymer material, a glass material, a ceramic material, or combinations of these. In some embodiments, the housing 310 may define one or openings, such as the opening 316, to allow input to or output from the electronic device 300.

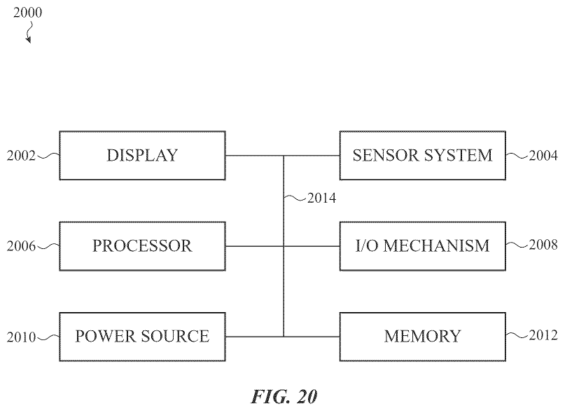

The housing 310 and the foldable cover 320 may together form the enclosure 305. The enclosure may define an internal cavity 307 and electronic components, such as the electronic components 381, 382, and 383, may be positioned at least partially within the internal cavity 307. The electronic components 381, 382, and 383 may be all or some of the device components described with respect to FIG. 20. For example, the electronic device 300 may include one or more of a display assembly, a processor, a power source, a sensor system (e.g., an optical sensor system or a camera), an input/output mechanism, a wireless communication or charging component, or a memory. As specific examples, the electronic device may include one or more audio components, cameras, sensors (e.g., infrared sensors), and the like. The electronic device may also include electronic circuitry operably connected to the device components. In some examples, the electronic device 300 includes a first camera that is positioned adjacent the foldable cover 320 and a second camera that is positioned adjacent the housing 310.

FIGS. 4A and 4B show magnified partial cross-sectional views of electronic devices that include a cover member defining a hinge. At least a portion of the hinge (438a, 438b) is thinner than other portions (431a, 431b, 432a, 432b) to facilitate bending of the cover member (430a, 430b). The examples of FIGS. 4A and 4B show different configurations of the coupling structure (450a, 450b). The electronic devices 400a, 400b may be examples of the device 100 and the cross-section may be taken along A-A in FIG. 1.

In the examples of FIGS. 4A and 4B, the cover member (430a, 430b) includes a hinge (438a, 438b) that is defined by a third portion (433a, 433b), a first intermediate portion (434a, 434b), alternately referred to herein as a fourth portion, and a second intermediate portion (435a, 435b), alternately referred to herein as a fifth portion of the cover member. The third portion (433a, 433b) has a thickness that is less than a thickness of each of the first portion (431a, 431b) and second portion (432a, 432b). The first intermediate portion (434a, 434b) may provide a first thickness transition between the first portion (431a, 431b) and the third portion (433a, 433b). The second intermediate portion (435a, 435b) may provide a second thickness transition between the second portion (432a, 432b) and the third portion (433a, 433b). The cover members 430a and 430b and portions and the foldable covers 420a and 420b thereof may be similar in composition and dimensions to those previously described for the cover member 330 and the cover 320.

The coupling structure (450a, 450b) is positioned between the cover member (430a, 430b) and the display assembly (460a, 460b). In the example of FIG. 4A, the coupling structure 450a has a substantially uniform thickness below the hinge 438a of the cover member 430a. In the example of FIG. 4B, the coupling structure 450b has a thickness below the third portion 433b of the cover member 430b that is greater than its thickness below the first portion 431b and the second portion 432b of the cover member 430b. The increased thickness of the coupling structure 450b below the third portion 433b of the cover member 430b may help reduce the curvature of the display assembly 460b and therefore produce less stress on the display assembly 460b in one or more configurations of the cover 420b and the cover member 430b. The variable thickness of the coupling structure 450b may be achieved by adjustment of the number, placement, and thickness of the layers that define the coupling structure 450b. The coupling structures 450a and 450b may be similar in composition to the coupling structure 350.

The examples of FIGS. 4A and 4B also includes a coating (440a, 440b) disposed over an exterior surface of the cover member (430a, 430b). The coating (440a, 440b) may be similar in composition and structure to the coating 340. The description provided with respect to the coating 340 is generally applicable herein.

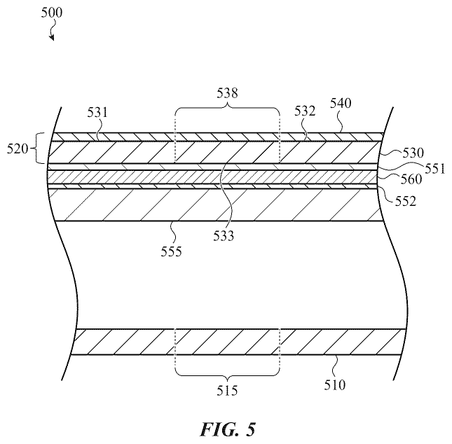

FIG. 5 shows another partial cross-sectional view of an electronic device. In the example of FIG. 5, the electronic device 500 includes a foldable cover 520 positioned over and coupled to a front surface of the display assembly 560 and a flexible plate 555 coupled to a rear surface of the display assembly 560. The flexible plate 555 may be configured to help control the folding of the electronic device. In some embodiments, a region of the flexible plate 555 that is positioned below the hinge 538 and the third portion 533 of the cover member 530 may have a stiffness value that is less than a stiffness value of regions of the flexible plate 555 that are positioned below the first and the second portions 531, 532 of the cover member 530. The electronic device 500 also includes a first coupling structure 551 between the cover member 530 and the display assembly 560 and a second coupling structure 552 between the display assembly 560 and the flexible plate 555. The electronic device 500 also include an exterior coating 540, which may be similar in composition and structure to the exterior coating 340.

The foldable cover 520 and the electronic device 500 are shown in an unfolded configuration in FIG. 5. The electronic device 500 may be an example of the device 100 and the cross-section may be taken along A-A in FIG. 1. The foldable cover 520, the display assembly 560, the housing 510, the mechanical hinge component 515, and the coupling structure 551 may be similar to the foldable cover 320, the display assembly 360, the housing 310, the multipart hinge component 315, and the coupling structure 350. The coupling structure 552 may be similar to or different from the coupling structure 551. In alternate embodiments, the electronic device 500 may include a rear cover that includes a hinge structure similar to that of the foldable cover 520.

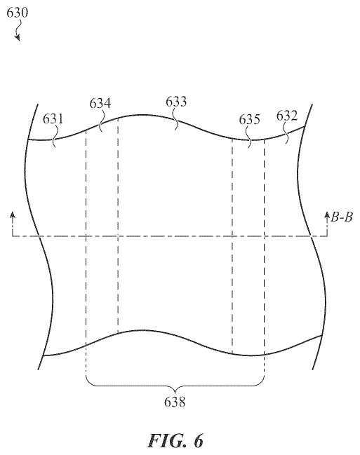

FIG. 6 shows a magnified top view of a cover member for an electronic device. The cover member 630 defines a hinge 638 positioned between and contiguous with a first portion 631 and a second portion 632 of the cover member 630. In the example of FIG. 6, the hinge 638 includes a third portion 633 as well as a first intermediate portion 634 and a second intermediate portion 635 of the cover member 630. In a similar fashion as described with respect to FIG. 3, the third portion 633 may have a thickness that is less than a thickness of each of the first portion 631 and a second portion 632 of the cover member 630 in order to facilitate bending of the cover member 630. The cover member 630 and portions thereof may be similar in composition, properties and dimensions to the cover members 330 and 730 and that description is not repeated here.

FIG. 7 shows an example of a partial cross-sectional view of a cover member defining a hinge that varies in thickness. The hinge 738 is positioned between and contiguous with a first portion 731 and a second portion 732 of the cover member 730. The hinge 738 includes a third portion 733 of the cover member that has a third thickness T₃ that is less than a first thickness of the first portion 731 and the second thickness of the second portion 732 of the cover member 730 (e.g., the thickness T₁ in the example of FIG. 7). The third portion 733 of the cover member defines a third width W₃. The cover member 730 may be an example of the cover member 630 and the cross-section may be taken along B-B in FIG. 6.

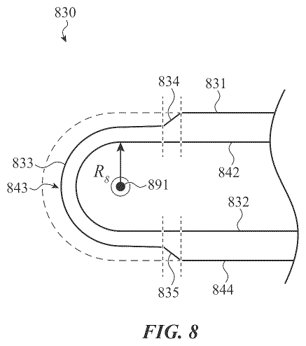

When the cover member 730 is in a folded configuration, the third portion 733 defines at least a portion of a bend in the cover member 730. The reduced thickness of the third portion 733 can therefore facilitate bending of the cover member 730 by reducing the maximum tensile stress in the folded configuration of the cover member 730. The third region 753b of the interior surface 744 of the cover member 730 that is defined by the third portion 733 may define the outside of the bend, as shown in the example of FIG. 8.

As shown in FIG. 7, the cover member 730 further includes a first intermediate portion 734 and a second intermediate portion 735. The first intermediate portion 734 is positioned between and is contiguous with the first portion 731 and the third portion 733 of the cover member 730. The first intermediate portion 734 provides a thickness transition between the first portion 731 and the third portion 733 of the cover member. Stated differently, the thickness of the first intermediate portion 734 transitions from a first thickness (T₁) to the third thickness (T₃). The fourth region 754b of the interior surface 744 defined by the first intermediate portion 734 may define an exterior angle theta (θ) with respect to the first region 751b of the interior surface 744 defined by the first portion 731.

Similarly, the second intermediate portion 735 is positioned between and is contiguous with the second portion 732 and the third portion 733 and provides a thickness transition between the second portion 732 and the third portion 733. In the example of FIG. 7, the thickness of the second intermediate portion 735 transitions from a second thickness (T₁) to the third thickness (T₃). The fifth region 755b of the interior surface 744 defined by the second intermediate portion 735 may also define an angle theta (θ) with respect to a second region 752b of the interior surface 744 defined by the second portion. In some cases, the angle theta (θ) is in a range from 2 degrees to 10 degrees, or from 2 degrees to 8 degrees.

The first intermediate portion 734 defines a fourth width W₄ and the second intermediate portion 735 defines a fifth width W₅. In some embodiments, the third width W₃ of the third portion 733 is greater than the fourth and the fifth widths W₄ and W₅ of the first and the second intermediate portions 734, 735. In some examples, a ratio of the third width W₃ to the fourth width W₄ may be in a range from 3 to 35 and a ratio of the third width W₃ to the fifth width W₅ may be in a range from 3 to 35. The first portion 731 further defines a first width and the second portion 732 further defines a second width. In some embodiments, the first width and the second width are substantially equal to each other while in other embodiments, the first width and the second width are different. In some cases, the first width of the first portion is greater than each of the third width W₃, the fourth width W₄, and the fifth width W₅. The second width of the second portion may be greater than each of the third width W₃, the fourth width W₄, and the fifth width W₅. In some embodiments, each of the fourth width W₄ and the fifth width W₅ is in a range from 0.5 mm to 10 cm, such as from 0.5 mm to 1 cm, 1 mm to 10 mm, or from 1 cm to 5 cm.

In the example of FIG. 7, the third region 753a of the exterior surface 742 defined by the third portion 733 is not substantially recessed with respect to the first region 751a, the second region 752a, the fourth region 754a, or the fifth region 755a of the exterior surface 742 defined by the first portion 731, the second portion 732, the first intermediate portion 734, and the second intermediate portion 735, respectively. Stated differently, the fourth region 754a of the exterior surface 742 is even with (alternately, aligned with) the first and the third regions (751a, 753a) of the exterior surface 742 and the fifth region 755a of the exterior surface 742 is even with the second and the third regions (752a, 753a) of the exterior surface 742.

However, the third region 753b of the interior surface 744 defined by the third portion 733 is substantially recessed with respect to the regions 751b and 752b of the interior surface 744 that are defined by the first portion 731 and the second portion 732. The third region 753b, the fourth region 754b, and the fifth region 755b of the interior surface 744 together define a recess 748.

FIG. 8 shows an example of a partial cross-section of a cover member in a folded configuration. The cover member 830 is bent around a bend axis 891 and defines a bend 843 in the folded configuration. In the example of FIG. 8, the bend is defined by a third portion 833 of the cover member 830 that has a reduced thickness as compared to the first portion 831 and the second portions 832. The first portion 831, the second portion 832, the third portion 833, the first intermediate portion 834, and the second intermediate portion 835 of the cover member 830 may be similar in composition and dimensions to the first portion 731, the second portion 732, the third portion 733, the first intermediate portion 734, and the second intermediate portion 735 of the cover member 730.

The third portion 833 may have a thickness that is less than a thickness of each of the first portion 831 and the second portion 832 of the cover member 830 in order to facilitate bending of the cover member 830. The region of the interior surface 844 of the cover member that is defined by the third portion 833 may define the outside of the bend 843 and may therefore be subjected to bending-induced tensile stress in the folded configuration of the cover member 830. The third portion 833 defines a bend radius R₈. In some embodiments, the bend radius R₈ may be in a range from 1 mm to 10 mm, from 5 mm to 10 mm, from 2 mm to 7 mm, or from 1 mm to 5 mm. The third portion 833 may also define a bend angle in a similar fashion as previously discussed with respect to FIGS. 2A and 2B. In some embodiments, the bend angle may be about 180 degrees or may be greater than 180 degrees. Each of the first portion 831, the second portion 832, and the third portion 833of the cover member also define respective regions of the exterior surface 842.

FIG. 9 shows an example of a top view of strengthened cover member defining a hinge. The cover member 930 may be strengthened to have different patterns of ion exchange and compressive stress, as generally indicated by the different levels of shading in FIG. 9. A third portion 933, a first intermediate portion 934, and a second intermediate portion 935 may together define a hinge 938 of the cover member, in a similar fashion as previously described with respect to FIG. 7. In some embodiments, each of the first portion 931, the second portion 932, the third portion 933, the first intermediate portion 934, and the second intermediate portion 935 of the cover member 930 is similar in composition and dimensions to the first portion 731, the second portion 732, the third portion 733, the first intermediate portion 734, and the second intermediate portion 735 of the cover member 730, respectively. The example of FIG. 9 is not intended to be limiting and in other embodiments, the intermediate portions need not be present.

Different portions of the cover member 930 may have different stress patterns. As indicated in FIG. 9, the stress patterns within the hinge 938 differ from those in the first portion 931 and the second portion 932. Furthermore, the stress pattern in the third portion 933 may differ from the stress patterns in the first intermediate portion 934 and the second intermediate portion 935.

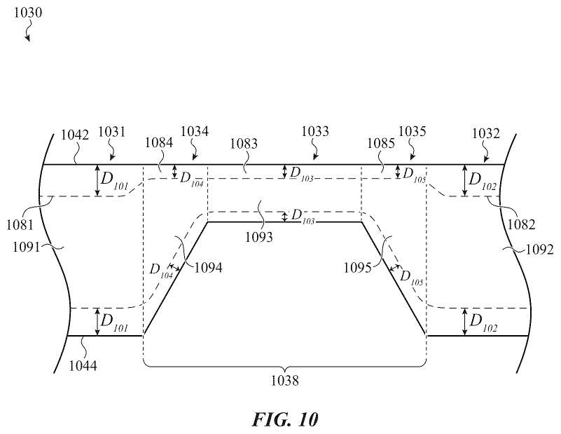

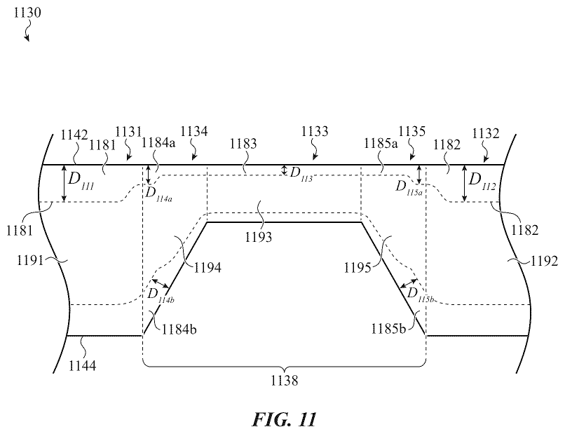

In embodiments described herein, one or more of the cover member portions 933, 934, and 935 that define the hinge 938 may be strengthened differently than the portions 931 and 932 to provide the cover member with a balance of properties. For examples, the stress patterns of the portions 931 through 935 of the cover member 930 may provide a balance between facilitating bending of the hinge 938, providing damage resistance to the cover member as a whole, and, in some cases, minimizing distortion of graphical output from the display assembly by the hinge 938. Examples of stress patterns of a cover member having a three-part hinge similar to that of FIG. 9 are shown in FIGS. 10, 11, and 12.

In some embodiments, the stress pattern in a given portion of the cover member includes a compressive region extending from an exterior surface of the cover member (alternately referred to as an exterior compressive region or a front compressive region), a compressive region extending from an interior surface of the cover member (alternately referred to as an interior compressive region or a rear compressive region), and a tensile region positioned between these two compressive regions. A given compressive region may define a compressive stress profile, a surface compressive stress, a maximum compressive stress, and a depth of the compressive region from its respective surface. In some cases, multiple measurements of one or more of the surface compressive stress, the maximum compressive stress, and the depth of the compressive region may be averaged to obtain a characteristic surface compressive stress, maximum compressive stress, and/or depth of the compressive region for a given portion of the cover member. The tensile region may define a tensile stress profile and a maximum tensile stress. Similarly, multiple measurements may be averaged to obtain a characteristic maximum tensile stress.

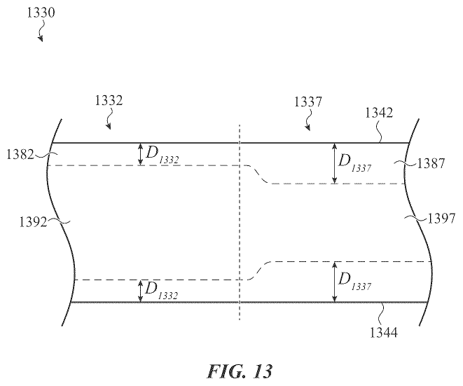

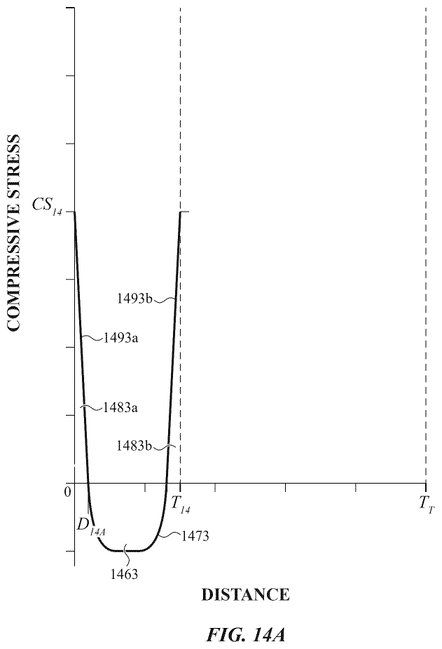

In some cases, the cover member 930 of FIG. 9 may have a first stress pattern in the first portion 931, a second stress pattern in the second portion 932, a third stress pattern in the third portion 933, a fourth stress pattern in the first intermediate portion 934 (if present), and a fifth stress pattern in the second intermediate portion 935 (if present). One or more additional stress patterns may be present in a peripheral portion of the cover member 930, as described with respect to FIG. 13. This description of the different stress patterns in the cover member 930 is not limited to the example of FIG. 9 and may be applicable to other cover members described herein, including the cover member 730 of FIG. 7.

The compressive regions of the stress patterns may be referred to accordingly in the description and claims. For example, a cover member may include one or more of a first exterior compressive region and a first interior compressive region in a first portion of the cover member, a second exterior compressive region and a second interior compressive region in a second portion of the cover member, a third exterior compressive region and a third interior compressive region in a third portion of the cover member, a fourth exterior compressive region and a fourth interior compressive region in a first intermediate portion of the cover member (if present), a fifth exterior compressive region and a fifth interior compressive region in a second intermediate portion of the cover member (if present), and one or more exterior and interior compressive regions in peripheral portion(s) of the cover member (if present, such as a sixth exterior and interior compressive region), examples of which are described below. Each of these compressive regions may have a respectively identified compressive stress profile, surface compressive stress, maximum compressive stress, a depth of the compressive region from its respective surface, and maximum tensile stress (e.g., a first compressive region may have a first compressive stress profile, a first compressive region depth, and a first surface compressive stress).

The cover member may further include one or more of a first tensile region in the first portion of the cover member, a second tensile region in the second portion of the cover member, a third tensile region in the third portion of the cover member, a fourth tensile region in the first intermediate portion of the cover member (if present), a fifth tensile region in the second intermediate portion of the cover member (if present), and one or more tensile regions in peripheral portions(s) of the cover member (if present, such as a sixth tensile region in a peripheral portion). Each of these tensile regions may have a respectively identified maximum tensile stress (e.g., a first tensile region may have a first maximum tensile stress).

In some examples, a stress pattern may be generally symmetric, so that the compressive regions at the exterior and the interior surfaces have a substantially similar compressive stress profile, with a similar surface compressive stress and a similar compressive region depth. In these examples, a compressive region at the exterior surface may be referred to as being symmetric with a compressive region at the interior surface in a given portion of the cover member. In some cases, a stress pattern may be referred to herein as substantially symmetric or symmetric when a compressive region depth and/or surface compressive stress of the compressive regions at the exterior and the interior surface is the same to within 5%. In some embodiments, all the stress patterns in the cover member are substantially symmetric, while in other embodiments at least one of the stress patterns in the cover member is asymmetric (e.g., with a variation of more than 10% between the surface compressive stress at the exterior and the interior surfaces and/or between the depth of the exterior and the interior compressive regions). In some examples, symmetry of a stress pattern may be assessed for a portion of the cover member as a whole or along the thickness at a specified location in the portion of the cover member. Examples of stress patterns are shown in FIGS. 10-12 and 17 and the description provided with respect to these figures is generally applicable herein.

The stress pattern may be formed by a process that includes one or more ion-exchange operations. The process typically includes at least one operation in which smaller ions in the ion-exchangeable material are exchanged for larger ions in order to create a compressive region. For example, if the ion-exchangeable material comprises sodium ions, the sodium ions may be exchanged for potassium ions. In some embodiments, the ion-exchangeable material may be capable of exchanging ions within the glass with two different types of larger ions, alternately referred to herein as dual ion exchange. For example, if the as-formed composition of the ion-exchangeable material comprises lithium ions, the lithium ions may be exchanged for sodium ions and/or potassium ions, as discussed in more detail below, including with respect to the examples of FIGS. 17-19. In some embodiments, the process may further include an operation of exchanging larger ions which have been introduced into the ion-exchangeable material with smaller ions (e.g., to reduce a level of surface compressive stress).

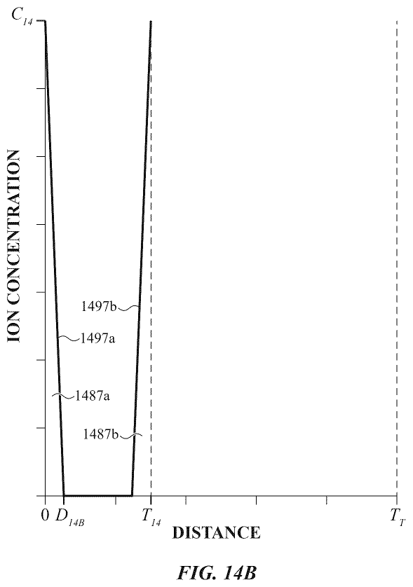

In some embodiments, the one or more ion exchange operations create an ion-exchanged layer at each of the interior and the exterior surfaces of the cover member. An ion-exchanged layer extending from the interior surface may alternately be referred to as an interior ion-exchanged layer or as a rear ion-exchanged layer. An ion-exchanged layer extending from the exterior surface may alternately be referred to as an exterior ion-exchanged layer or a front ion-exchanged layer. Each ion-exchanged layer defines a respective depth, which in some cases may differ from the compressive region depth. The depth of a rear ion-exchanged layer may be referred to as a rear depth and the depth of a front ion-exchanged layer may be referred to as a front depth. Each ion-exchanged layer also typically defines an ion-concentration profile for each of the types of ions that have been introduced into the cover member through ion exchange. Examples of ion concentration profiles are described in more detail with respect to FIGS. 14, 15A, 15B, and 19 and the description provided with respect to these figures is generally applicable herein. Each ion-exchanged layer may also define a maximum concentration for an ion that has been introduced into the cover member through ion exchange (e.g., a first ion-exchanged layer in the first portion of the cover member may define a first maximum concentration of sodium ions and/or potassium ions).

The cover member may have multiple ion exchange patterns. In some cases, the cover member 930 of FIG. 9 may have a first ion exchange pattern in the first portion 931, a second ion exchange pattern in the second portion 932, a third ion exchange pattern in the third portion 933, a fourth ion exchange pattern in the first intermediate portion 934, and a fifth ion exchange pattern in the second intermediate portion 935. One or more additional ion-exchange patterns may be present in a peripheral portion of the cover member 930. This description of the different ion exchange patterns in the cover member 930 is not limited to the example of FIG. 9 and may be applicable to other cover members described herein, including the cover member 730 of FIG. 7.

The ion-exchanged layers of the ion exchange patterns may be referred to accordingly in the description and claims. For example, a cover member may include one or more of a first exterior ion-exchanged layer and a first interior ion-exchanged layer region in a first portion of the cover member, a second exterior ion-exchanged layer and a second interior ion-exchanged layer in a second portion of the cover member, a third exterior ion-exchanged layer and a third interior ion-exchanged layer in a third portion of the cover member, a fourth exterior ion-exchanged layer and a fourth interior ion-exchanged layer in a first intermediate portion of the cover member (if present), a fifth exterior ion-exchanged layer and a fifth interior ion-exchanged layer in a second intermediate portion of the cover member (if present), and a sixth exterior ion-exchanged layer and a sixth interior ion-exchanged layer in a peripheral portion of the cover member (if present), and so forth, examples of which are described below. Each of these ion-exchanged layers may have a respectively identified depth, ion concentration profile, and maximum ion concentration (e.g., a first rear ion-exchanged layer in the first portion of the cover member may have a first rear depth).

Strengthening by exchanging smaller ions in the ion-exchangeable material for larger ions can cause expansion of the ion-exchangeable material. In embodiments described herein, the strengthening of the cover member may be configured to minimize shape change of the hinge that may occur when expansion of a portion of the hinge is constrained by another portion of the cover member. In some cases, the strengthening of the cover member is configured to maintain planarity of one or more surfaces of the hinge to within a specified tolerance level in order to minimize distortion by the hinge of graphical output from the display assembly. As examples, the magnitude of the maximum value out of plane displacement of a hinge surface may be less than 0.75 micrometers, less than 0.5 micrometers, or less than 0.25 micrometers, such that the hinge surface is flat to within the specified tolerance. Furthermore, a maximum value of the distance between high and low points on the hinge surface may be less than or equal to 1 micrometer or less than or equal to 0.5 micrometers. These values may be measured away from an edge of the cover member.

When a portion of the cover member has a stress pattern that is substantially symmetric, an in-plane expansion value of that portion in a plane perpendicular to this thickness may be an average strain value that is constant through the thickness of the cover member. In some cases, the average strain value may be approximated to obtain an in-plane expansion value. When the stress pattern is asymmetric, the in-plane expansion value may not be constant through the thickness of the cover member. The in-plane expansion value may be calculated from the profile(s) of ion concentration as function of depth and the relationship(s) between expansion and ion concentration and may be inversely proportional to the thickness. In some cases, an average expansion value may be calculated from an integral over the thickness of the cover member of a product of an ion concentration at a given depth and the relationship between expansion and ion concentration for that concentration value. This integral may be divided by the thickness to obtain the average expansion value. When more than one type of ion is introduced into the cover, this integral may consider each type of ion. The in-plane expansion value near the periphery of the cover member may be different from the in-plane expansion value away from the periphery.

In some embodiments, an in-plane expansion value of a hinge defined by the cover member is matched to an in-plane expansion value of another portion of the cover member in order to minimize undesirable shape change within the hinge. In one example, a third in-plane expansion value of the third portion 933, is matched to a first in-plane expansion value of the first portion 931 and to a second in-plane expansion value of the second portion 932 of the cover member. Alternately or additionally, the third in-plane expansion value of the third portion 933 is matched to a fourth in-plane expansion value of the first intermediate portion 934 and a fifth in-plane expansion value of the second intermediate portion 935. In some embodiments, two in-plane expansion values are matched when they differ by no more than 15% or no more than 10% of the smaller value. In some cases, matching of the in-plane expansion value between the two portions of the cover member may be assessed by comparison of the ratios of the depth of the ion exchanged layer to the thickness of the cover member. In some examples, this comparison may be valid for a symmetrically strengthened portion of the cover where the ion concentration profile has a substantially constant slope over a relatively large portion of the profile.

The different stress patterns in the cover member may be produced by various methods. In some embodiments, multiple ion exchange operations are used to produce the different stress patterns. In some cases, only selected portions of the cover member are exposed to the ion-exchange medium during a given ion exchange operation. As one example, one or more portions of the hinge (e.g., 933) may be masked and other portions of the cover member exposed to a first ion-exchange medium in a first ion exchange operation. The mask may be removed and each of the portions 931, 932, 933, 934, and 935 exposed to a second ion exchange medium, which may be the same as or different from the first ion exchange medium. The ion exchange medium may be a bath or a paste.

The mask may be designed to provide full or partial blocking of ion exchange. In some embodiments a mask may be designed to effectively block ion exchange of a portion of the cover member during the ion exchange operation. In other embodiments, a mask may be designed to only partially block ion exchange of the portion of the cover. In some cases, the permeability of the mask material to ions may depend on the thickness of the mask, with a thicker mask having a greater ability to block ion exchange. In these embodiments, a mask may be designed to have a thickness gradient in order to produce a compressive region that varies along a surface of a portion of the cover member. Examples of mask materials include, but are not limited to, silicon dioxide, silicon nitride, silicon oxynitride, and aluminum oxynitride.

Each of the multiple ion exchange operations may be designed to produce the same type of ion exchange or different ion exchange operations may be designed to produce different types of ion exchange. As one example, each of the ion exchange operations may exchange sodium for potassium. As another example one of the ion exchange operations may exchange lithium for sodium and another ion exchange operation may exchange lithium or sodium for potassium. Furthermore, an ion exchange operation may be designed to produce some amount of back exchange. In some embodiments, the ion-exchange medium may include some of the ions initially present in the cover member. For example, a compressive region formed by exchanging sodium for potassium may be modified by exchanging some of the potassium introduced into the cover member for sodium, thereby reintroducing sodium ions into the cover.

In some embodiments, selective heating may be used to modify the compressive regions formed within the part. For example, local heating of a compressive region in a portion of the cover member (without introducing additional ions) may be used to increase the depth of layer while decreasing the surface compressive stress. As another example, local heating of a portion of the cover member of during an ion exchange operation may be used to increase diffusion of ions from the ion exchange medium into the portion of the cover member.

FIGS. 10, 11, and 12 show examples of partial cross-sectional views of strengthened cover members. In the examples of each of FIGS. 10, 11, and 12, the strengthened cover member defines a hinge that is strengthened differently than other portions of the cover member. In these examples, the hinge (1038, 1138, 1238) is defined by a third portion of the cover member together with first and second intermediate portions of the cover member. The hinge may be thinner than the first and the second portions of the cover member, as was previously described with respect to FIG. 7. The partial cross-sectional views of FIGS. 10, 11, and 12 may be examples of cross-sectional view of the cover member 930 of FIG. 9.

The stress patterns created by strengthening the cover member may, in combination, limit shape changes of the hinge that can distort graphical output from the display assembly. In some embodiments, the stress patterns in the different portions of the cover member may be configured to produce similar in-plane expansion values. In some embodiments, the stress patterns of the first and the second portions (e.g., 1031, 1032 of FIG. 10) of the cover member may be configured to produce in-plane expansion values that are matched to those of the third portion (e.g., 1033 of FIG. 10) of the cover member. Furthermore, the stress patterns of the first and the second intermediate portions (e.g., 1034, 1035 of FIG. 10) of the cover member may be configured to produce in-plane expansion values that do not lead to undue distortion of the third portion (e.g., 1033) of the cover member. In some cases, the cover member may be configured so that the in-plane expansion values of the first and the second portions and the in-plane expansion values of the first and the second intermediate portions do not lead to undue deviations from planarity of the exterior and interior surfaces of the third portion of the cover member in the unfolded configuration.

The individual stress patterns may also provide specific benefits to the respective portions of the cover member. For example, the stress pattern within a third portion (e.g., 1033 of FIG. 10) of the cover member that defines a bend in a folded configuration of the electronic device can compensate at least in part for bending-induced tensile stresses. The stress patterns within the first and the second portions of the cover member (e.g., 1031, 1032 of FIG. 10) can provide increased damage protection as compared to the third portion.

In the example of FIG. 10, the third symmetric stress pattern of the thinner third portion 1033 is different from each of the first symmetric stress pattern of the first portion 1031 and the second symmetric stress pattern of the second portion 1032. Although each of the first, second, and third symmetric stress patterns include compressive regions at the interior surface 1044 and the exterior surface 1042 of the cover member, the third compressive regions 1083 of the third portion 1033 are different from each of the first compressive regions 1081 of the first portion 1031 and the second compressive regions 1082 of the second portion 1032.

As shown in the example of FIG. 10, the depth D₁₀₃ of the third compressive regions 1083 is less than the depth D₁₀₁ of the first compressive regions 1081 and the depth D₁₀₂ of the second compressive regions 1082. Limiting the depth D₁₀₃ of the third compressive regions 1083 may help limit the average in-plane expansion value. Alternately or additionally, limiting the depth D₁₀₃ of the third compressive regions 1083 may help to maintain relatively high levels of compressive stress at or near the surface and/or may help to limit the maximum central tension within the third portion 1033 of the cover member 1030. The depth D₁₀₃ may be greater than zero and less than each of the depth D₁₀₁ and the depth D₁₀₂. In some embodiments, the depth D₁₀₃ may be greater than zero and less than or equal to a depth limit for the hinge, which in some cases may be less than or equal to 20% of the thickness of the third portion 1033. For example, the depth D₁₀₃ may be greater than 2 micrometers and less than or equal to 20% of the thickness of the third portion 1033. In some cases, the depth D₁₀₃ may be greater than or equal to 10% and less than or equal to 20% of the thickness of the third portion 1033. The third compressive regions 1083 may also differ from the compressive regions 1081 and 1082 with respect to one or more of surface compressive stress values, maximum central tension values, composition, and the general shape of the compressive stress profile, as explained in more detail below.

As previously discussed, the fourth stress pattern of the first intermediate portion 1034 and the fifth stress pattern of the second intermediate portion 1035 may be configured to produce in-plane expansion values that do not lead to undue distortion of the third portion 1033 of the cover member. In the example of FIG. 10, each of the depth D₁₀₄ of the fourth compressive regions 1084 and the depth Dios of the fifth compressive regions 1085 is similar to the depth D₁₀₃ of the third compressive regions 1083. In embodiments where the fourth compressive regions 1084 and the fifth compressive regions 1085 are generally similar to the third compressive regions 1083, the varying thickness of the first intermediate portion 1034 and the second intermediate portion 1035 may produce an in-plane expansion value that decreases with increasing thickness. In these embodiments, the cover member 1030 may define an inclination angle theta (θ) (previously shown in FIG. 7) that is sufficiently small to produce a sufficiently gradual change in the in-plane expansion value in the first intermediate portion 1034 and the second intermediate portion 1035. The examples of inclination angle values previously discussed with respect to FIG. 7 are generally applicable herein.

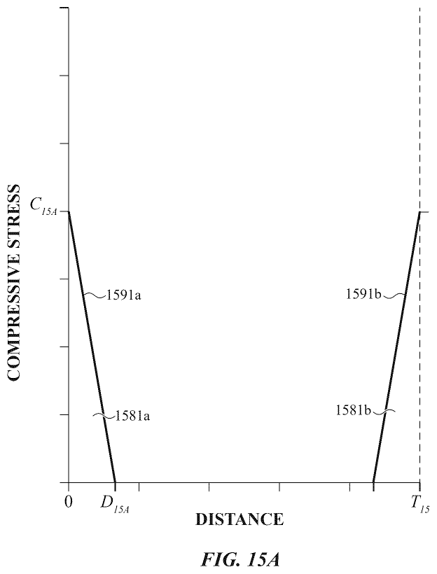

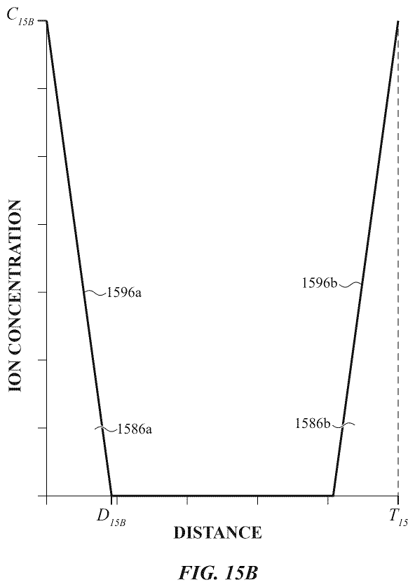

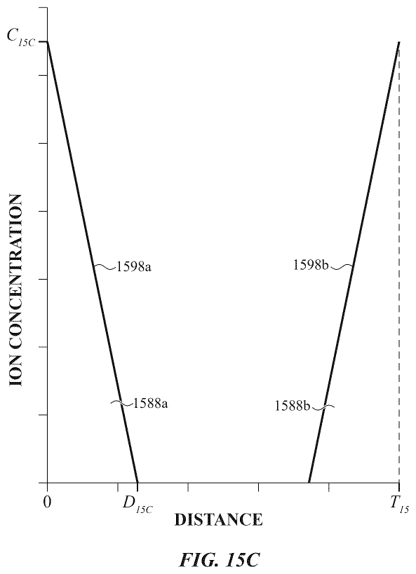

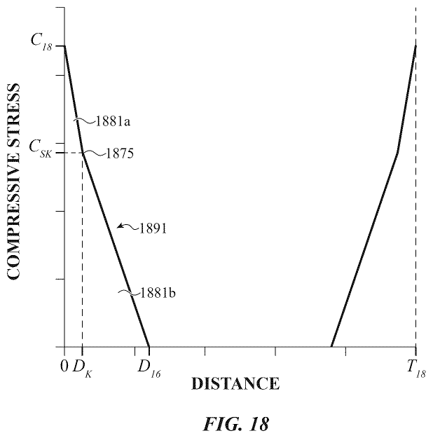

In the example of FIG. 10, the first portion 1031 of the cover member 1030 defines a first symmetric stress pattern. The first symmetric stress pattern includes a first compressive region 1081 extending from each of an exterior surface 1042 and an interior surface 1044 of the cover member. Each of the first compressive regions 1081 define a first depth D₁₀₁. Each of the first compressive regions 1081 also define a first surface compressive stress. An example of a compressive stress profile that may be present in the first compressive regions 1081 are described with respect to FIGS. 15A, 15C, and 18 and the description provided with respect to these figures is generally applicable herein. The first symmetric stress pattern also includes a first tensile region 1091 between these two compressive regions that defines a first maximum tensile stress.

The first portion 1031 of the cover member 1030 also defines a first ion concentration profile, as previously discussed with respect to FIG. 9. In some examples, the first ion concentration profile may be a profile of potassium ions that have replaced sodium ions in the cover member, examples of which are shown in FIG. 15B. In some cases, the first portion 1031 of the cover member may define one or more other ion concentration profiles, such as an ion concentration profile of the ions present in the initial (as-formed) composition of the glass or an ion concentration profile of another type of ions introduced into the cover member. As previously discussed with respect to FIG. 9, the first symmetric stress profile may produce a first in-plane expansion value that is uniform through the thickness of the cover member 1030.

The second portion 1032 of the cover member 1030 defines a second symmetric stress pattern. The second symmetric stress pattern includes a second compressive region 1082 extending from each of an exterior surface 1042 and an interior surface 1044 of the cover member and having a second depth D₁₀₂ and a second surface compressive stress. Compressive stress profiles that may be present in the second compressive regions 1082 are described with respect to FIGS. 15A, 15B, and 18 and the description provided with respect to these figures is generally applicable herein. The second symmetric stress pattern also includes a second tensile region 1092 between these two compressive regions 1082, the second tensile region defines a second maximum tensile stress. The second portion 1032 of the cover member 1030 also defines a second ion concentration profile and a second in-plane expansion value that is uniform through the thickness of the cover member 1030. In some cases, the second portion 1032 of the cover member may define one or more other ion concentration profiles, such as an ion concentration profile of the ions present in the initial (as-formed) composition of the glass or an ion concentration profile of another type of ions introduced into the cover member. The second symmetric stress pattern may be balanced with the first symmetric stress pattern, so that these two stress patterns may have a similar depth and compressive surface stress and produce similar in-plane expansion values.

The third portion 1033 of the cover member 1030 defines a third symmetric stress pattern. The third symmetric stress pattern includes a third compressive region 1083 extending from each of an exterior surface 1042 and an interior surface 1044 of the cover member and having a third depth D₁₀₃. Compressive stress profiles that may be present in the third compressive regions 1083 are described with respect to FIG. 14 and the description provided with respect to these figures is generally applicable herein. The third symmetric stress pattern also includes a third tensile region 1093 between these two compressive regions 1083 that defines a maximum tension value.

In some embodiments, the third surface compressive stress may be greater than or equal to each of the first surface compressive stress and the second surface compressive stress. As previously discussed, strengthening the cover member 1030 to produce surface compressive stress at the interior surface of the third portion 1033 of the cover member 1030 can help counteract bending-induced tensile stress at the interior surface when the cover member is folded. However, it may be advantageous to provide a lower surface compressive stress in the first portion 1031 and the second portion 1032 of the cover in order to provide a deeper compressive region without creating an undue amount of expansion in the cover member due to ion exchange.

The third portion 1033 of the cover member 1030 also defines a third ion concentration profile and a third in-plane expansion value that is uniform through the thickness of the cover member 1030. In some cases, the third portion 1023 of the cover member may define one or more other ion concentration profiles, such as an ion concentration profile of the ions present in the initial (as-formed) composition of the glass or an ion concentration profile of another type of ions introduced into the cover member. The third depth D₁₀₃ may be less than or equal to a depth limit for the hinge, as previously discussed with respect to FIG. 10. The third maximum tension value may be greater than each of the first maximum tension value and the second maximum tension value.

The first intermediate portion 1034 (alternately referred to as the fourth portion 1034) of the cover member 1030 defines a fourth stress pattern. The fourth stress pattern includes a fourth compressive region 1084 extending from each of an exterior surface 1042 and an interior surface 1044 of the cover member. Each of the fourth compressive regions 1084 defines a fourth depth D₁₀₄. Each of the fourth compressive regions 1084 also defines a fourth surface compressive stress. The fourth stress pattern also includes fourth tensile region 1094 between these two compressive regions 1084 that defines a fourth maximum tensile stress. The first intermediate portion 1034 of the cover member 1030 also defines a fourth ion concentration profile. As previously discussed, the first intermediate portion 1034 may define in-plane expansion value that varies with the thickness of the first intermediate portion 1034.

The second intermediate portion 1035 (alternately referred to as the second intermediate portion 1033) of the cover member 1030 defines a fifth stress pattern. The fifth stress pattern includes a fifth compressive region 1085 extending from each of an exterior surface 1042 and an interior surface 1044 of the cover member. Each of the fifth compressive regions 1085 defines a fifth depth D₁₀₅. Each of the fifth compressive regions 1085 also defines a fifth surface compressive stress. The fifth stress pattern also includes fifth tensile region 1095 between these two compressive regions 1085 that defines a fifth maximum tensile stress. The second intermediate portion 1035 of the cover member 1030 also defines a fourth ion concentration profile. As previously discussed, the second intermediate portion 1035 may define in-plane expansion value that varies with the thickness of the second intermediate portion 1035.

In some embodiments, the strengthening patterns in the example of FIG. 10 can be produced by strengthening the first and the second portions while blocking the hinge from ion exchange and then strengthening the first and the second portions and the hinge together in a subsequent ion exchange operation. In other embodiments, the hinge and the first and the second portions of the cover member 1030 may be strengthened separately.

FIG. 11 shows another example of a partial cross-sectional view of a strengthened cover member. Similarly to the example of FIG. 10, the third symmetric stress pattern of the thinner third portion 1133 is different from each of the first symmetric stress pattern of the first portion 1131 and the second symmetric stress pattern of the second portion 1132. However, the stress patterns in the first intermediate portion 1134 and the second intermediate portion 1135 are different from the example of FIG. 10.

As previously discussed, the fourth stress patterns of the first intermediate portion 1134 and the fifth stress patterns of the second intermediate portion 1135 may be configured to produce in-plane expansion values that do not lead to undue distortion of the third portion 1133 of the cover member. In the example of FIG. 11, the depth of the compressive regions 1184a, 1184b of the first intermediate portion and the depth of the compressive regions 1185a, 1185b of the second intermediate portion is not constant. The varying thickness of the first intermediate portion 1134 and the second intermediate portion 1135 and the change in depth of the compressive regions 1184a, 1184b, 1185a, 1185b in these portions of the cover member 1130 may produce a more limited decrease in the in-plane expansion value with increasing thickness as compared to the example of FIG. 10. The narrower range of in-plane expansion values in the first intermediate portion 1134 and the second intermediate portion 1135 may produce better matching of these in-plane expansion values with the in-plane expansion values of the third portion, as well as the first and the second portions. In some cases, the stress patterns shown in FIG. 11 may produce less shape change of the hinge than the stress patterns shown in the example of FIG. 10.

The first intermediate portion 1134 (alternately referred to as the fourth portion 1134) of the cover member 1130 defines a fourth stress pattern. The fourth stress pattern includes an exterior compressive region 1184a and an interior compressive region 1184b. In some embodiments, the fourth stress pattern is symmetric and in other embodiments the fourth stress pattern may be asymmetric. The fourth stress pattern also includes a fourth tensile region 1194 between these two compressive regions 1184a, 1185b that defines a fourth maximum tensile stress. The first intermediate portion 1134 of the cover member 1130 also defines ion concentration profiles in the compressive regions 1184a and 1184b.

In the example of FIG. 11, the depth of the compressive region 1184a is the same as the depth D₁₁₃ proximate the third compressive region 1183 and then increases to a depth D₁₁₄ₐ that is greater than the depth D₁₁₃ and less than or equal to the depth D₁₁₁ of the first portion. The depth of the compressive region 1184b is the same as the depth D₁₁₃ proximate the third compressive region 1183 in a second region of the first intermediate portion. In a first region of the second intermediate portion, the depth of the compressive region 1184a then increases to a depth D_{114b} that is greater than the depth D₁₁₃ and less than or equal to the depth D₁₁₁ of the first portion. Each of the compressive regions 1184a, 1184b also defines a respective surface compressive stress.

The second intermediate portion 1135 (alternately referred to as the second intermediate portion 1135) of the cover member 1130 defines a fifth stress pattern. The fifth stress pattern includes an exterior compressive region 1185a and an interior compressive region 1185b. In some embodiments, the fifth stress pattern is symmetric and in other embodiments the fifth stress pattern may be asymmetric. The fifth stress pattern also includes a fifth tensile region 1195 between these two compressive regions 1185 that defines a fifth maximum tensile stress. The second intermediate portion 1134 of the cover member 1130 also defines ion concentration profiles in the compressive regions 1185a and 1185b.

In the example of FIG. 11, the depth of the compressive region 1185a is the same as the depth D₁₁₃ proximate the third compressive region 1183 and then increases to a depth D₁₁₅ₐ that is greater than the depth D₁₁₃ and less than or equal to the depth D₁₁₂ of the second portion. The depth of the compressive region 1185b is the same as the depth D₁₁₃ proximate the third compressive region 1183 in a second region of the second intermediate portion. In a first region of the second intermediate portion, the depth of the compressive region 1185b increases to a depth D_{115b} that is greater than the depth D₁₁₃ and less than or equal to the depth D₁₁₂ of the second portion.

Although each of the first, second, and third symmetric stress patterns include compressive regions at the interior and the exterior surface of the cover member, the third compressive regions 1183 of the third portion 1133 are different from each of the first compressive regions 1181 of the first portion 1131 and the second compressive regions 1181 of the second portion 1132. As shown in the example of FIG. 11, the depth D₁₁₃ of the third compressive regions 1183 is less than the depth Din of the first compressive regions 1181 and the depth D₁₁₂ of the second compressive regions 1182. The third compressive regions 1183 may also differ from the compressive regions 1181 and 1182 with respect to one or more of surface compressive stress values, maximum central tension values, composition, and the general shape of the compressive stress profile, in a similar fashion as previously described for FIG. 10.

The first portion 1131 of the cover member 1130 has a first stress pattern that includes the first compressive regions 1181 and a first tensile region 1191. As shown in FIG. 11, the first stress pattern is symmetric and the first compressive regions 1181 have a depth D₁₁₁. The second portion 1132 of the cover member 1130 has a second stress pattern that includes the second compressive regions 1181 and a second tensile region 1192. As shown in FIG. 11, each of the first and the second stress patterns is symmetric, the first compressive regions 1181 have a depth Din and the second compressive regions 1182 have depth D₁₁₂. Other properties of the first portion 1131 and the second portion 1132 of the cover member 1130 may be similar to those of the first portion 1031 and the second portion 1032 of the cover member 1030 and are not repeated here. The exterior surface 1142 and the interior surface 1144 of the cover member 1130 are also shown in FIG. 11.

The third portion 1133 of the cover member 1130 has a third stress pattern that includes the third compressive regions 1183 and third tensile region 1193. As shown in FIG. 11, the third stress pattern is symmetric, and the third compressive regions have depth D₁₁₃. Other properties of the third portion 1133 of the cover member 1130 may be similar to those of the third portion 1033 of the cover member 1030 and are not repeated here.

In some embodiments, the strengthening patterns in the example of FIG. 11 can be produced by differentially strengthening the first and the second portions 1131, 1132 and the first region of each of the first and the second intermediate portions 1134, 1135 while blocking strengthening of the third portion 1133 and the second regions of the first and the second intermediate portions 1134, 1135. For example, a partially transmissive mask may be applied to the first regions of the first and the second intermediate portions 1134, 1135 to provide a limited amount of ion exchange as compared to the first and the second portions 1131, 1132. As another example, an ion exchange medium with a lower concentration of ions may be applied to the first regions of the first and the second intermediate portions 1134, 1135 as compared to the first and the second portions 1131, 1132. The first and the second portions and the hinge may then be strengthened together in a subsequent ion exchange operation. In other embodiments, the third portion 1133 and the second regions of the first and the second intermediate portions 1134, 1135, the first regions of the first and the second intermediate portions 1134, 1135, and the first and the second portions 1131, 1132 of the cover member 1130 may be strengthened separately.

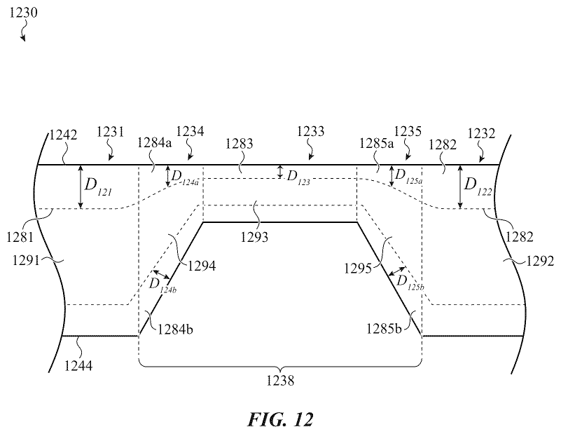

FIG. 12 shows another example of a partial cross-sectional view of a strengthened cover member. Similarly to FIGS. 10 and 11, the third symmetric stress pattern of the thinner third portion 1233 is different from each of the first symmetric stress pattern of the first portion 1231 and the second symmetric stress pattern of the second portion 1232. However, the stress patterns in the first intermediate portion 1234 and the second intermediate portion 1235 are different from the examples of FIGS. 10 and 11.

The fourth stress pattern of the first intermediate portion 1234 and the fifth stress pattern of the second intermediate portion 1235 may be configured to produce in-plane expansion values that do not lead to undue distortion of the third portion 1233 of the cover member. In the example of FIG. 12, the depth of the compressive regions 1284a, 1284b of the first intermediate portion and the depth of the compressive regions 1285a, 1285b of the second intermediate portion is not constant. Specifically, each of the compressive regions 1284a, 1284b, 1285a, and 1285b define a depth gradient, with the depth increasing with increasing thickness of the first intermediate portion 1234 and the second intermediate portion 1235. The varying thickness of the first intermediate portion 1234 and the second intermediate portion 1235 and the gradual change in depth of compressive regions 1284a, 1284b, 1285a, 1285b in these portions of the cover member 1230 may produce a narrower range of in-plane expansion values as compared to the example of FIG. 10 or FIG. 11. In some cases, the in-plane expansion value may be substantially constant in each of the first intermediate portion 1234 and the second intermediate portion 1235. The narrower range of in-plane expansion values in the first intermediate portion 1234 and the second intermediate portion 1235 may produce better matching of these in-plane expansion values with the in-plane expansion values of the third portion, as well as the first and the second portions. In some cases, the stress patterns shown in FIG. 12 may produce less shape change of the hinge than the stress patterns shown in the example of FIG. 10 or FIG. 11.

The first intermediate portion 1234 (alternately referred to as the fourth portion 1234) of the cover member 1230 defines a fourth stress pattern. The fourth stress pattern includes an exterior compressive region 1284a and an interior compressive region 1284b. In some embodiments, the fourth stress pattern is symmetric and in other embodiments the fourth stress pattern may be asymmetric. The fourth stress pattern also includes a fourth tensile region 1294 between these two compressive regions 1284a, 1285b that defines a fourth maximum tensile stress. The first intermediate portion 1234 of the cover member 1230 also defines ion concentration profiles in the compressive regions 1284a and 1284b.

In the example of FIG. 12, the depth of the compressive region 1284a is the same as the depth D₁₂₃ proximate the third compressive region 1283 and then gradually increases to a depth that approaches the depth D₁₂₁ of the first portion proximate the first compressive region 1281. The depth D₁₂₄ₐ is greater than the depth D₁₂₃ and less than or equal to the depth D₁₂₁ of the first portion. The depth of the compressive region 1284b is the same as the depth D₁₂₃ proximate the third compressive region 1283 and then gradually increases to a depth that approaches the depth D₁₂₁ of the first portion proximate the first compressive region 1281. The depth D_{124b} is greater than the depth D₁₂₃ and less than or equal to the depth D₁₂₁ of the first portion. In this example, the depth of each of the compressive regions 1284a and 1284b varies with the thickness of the first intermediate portion 1234. Each of the compressive regions 1284a, 1284b also defines a respective surface compressive stress. The depth of the front and the rear ion-exchanged layers in this example also vary with the thickness in the first intermediate portion 1234.

The second intermediate portion 1235 (alternately referred to as the fifth portion 1235) of the cover member 1230 defines a fifth stress pattern. The fifth stress pattern includes an exterior compressive region 1285a and an interior compressive region 1285b. In some embodiments, the fifth stress pattern is symmetric and in other embodiments the fifth stress pattern may be asymmetric. The fifth stress pattern also includes a fifth tensile region 1295 between these two compressive regions 1285 that defines a fifth maximum tensile stress. The second intermediate portion 1235 of the cover member 1230 also defines ion concentration profiles in the compressive regions 1285a and 1285b.

In the example of FIG. 12, the depth of the compressive region 1285a is the same as the depth D₁₂₃ proximate the third compressive region 1283 and then gradually increases to a depth that approaches the depth D₁₂₂ of the second portion. The depth D₁₂₅ₐ is greater than the depth D₁₂₃ and less than or equal to the depth D₁₂₂ of the second portion. The depth of the compressive region 1285b is the same as the depth D₁₂₃ proximate the third compressive region 1283 and then increases to a depth that approaches the depth D₁₂₂ of the second portion. The depth D_{125b} is greater than the depth D₁₂₃ and less than or equal to the depth D₁₂₂ of the second portion. In this example, the depth of each of the compressive regions 1285a and 1285b varies with the thickness of the second intermediate portion 1235. Each of the compressive regions 1285a, 1285b also defines a respective surface compressive stress. The depth of the front and the rear ion-exchanged layers in this example also vary with the thickness in the second intermediate portion 1235.

Although each of the first, second, and third symmetric stress patterns include compressive regions at the interior and the exterior surface of the cover member, the third compressive regions 1283 of the third portion 1233 are different from each of the first compressive regions 1281 of the first portion 1231 and the second compressive regions 1281 of the second portion 1232. As shown in the example of FIG. 12, the depth D₁₂₃ of the third compressive regions 1283 is less than the depth D₁₂₁ of the first compressive regions 1281 and the depth D₁₂₂ of the second compressive regions 1282. The third compressive regions 1283 may also differ from the compressive regions 1281 and 1282 with respect to one or more of surface compressive stress values, composition, and the general shape of the compressive stress profile, in a similar fashion as previously described for FIG. 10. The third tensile region 1293 may also differ from the tensile regions 1291 and 1292 with respect to the maximum tensile stress and other features in a similar fashion as previously described for FIG. 10.

The first portion 1231 of the cover member 1230 has a first stress pattern that includes the first compressive regions 1281 and a first tensile region 1291. As shown in FIG. 12, the first stress pattern is symmetric and the first compressive regions 1281 have a depth D₁₂₁. The second portion 1232 of the cover member 1230 has a second stress pattern that includes the second compressive regions 1282 and a second tensile region 1292. As shown in FIG. 12, the second stress pattern is symmetric and the second compressive regions 1282 have depth D₁₂₂. Other properties of the first portion 1231 and the second portion 1232 of the cover member 1230 may be similar to those of the first portion 1031 and the second portion 1032 of the cover member 1030 and are not repeated here. The exterior surface 1242 and the interior surface 1244 of the cover member 1230 are also shown in FIG. 12.

The third portion 1233 of the cover member 1230 has a third stress pattern that includes the third compressive regions 1283 and third tensile region 1293. As shown in FIG. 12, the third stress pattern is symmetric, and the third compressive regions have depth D₁₂₃. Other properties of the third portion 1233 of the cover member 1230 may be similar to those of the third portion 1033 of the cover member 1030 and are not repeated here.

In some embodiments, the strengthening patterns in the example of FIG. 12 can be produced by differentially strengthening the first and the second portions and the first and the second intermediate portions while blocking strengthening of the third portion. For example, during one ion exchange operation the first and the second portions may not be masked while a mask defining a transmission gradient may be applied to the first and the second intermediate portions. In another example, an ion exchange medium with a graded concentration of ions may be applied to the first and the second intermediate portions while an ion exchange medium with a constant and higher concentration of ions may be applied to the first and the second intermediate portions. The first and the second portions and the hinge may then be strengthened together in a subsequent ion exchange operation. In other embodiments, the third region, the first and the second intermediate portions, and the first and the second portions of the cover member 1230 may be strengthened separately.

FIG. 13 shows another example of a partial cross-sectional view of a strengthened cover member. In the example of FIG. 13, the peripheral portion of the strengthened cover member 1330 is strengthened differently than another portion of the cover member that is positioned away from the periphery. The peripheral portion may have a thickness that is substantially the same as the other portion of the cover member.

In the example of FIG. 13, the symmetric stress pattern of the peripheral portion 1337 is different from the symmetric stress pattern of the portion 1332, which positioned inwards from the peripheral portion. In some embodiments, the stress pattern within the peripheral portion 1337 can provide increased damage protection as compared to the portion 1332. The portion 1332 may be an example of the second portion of the cover members 1032, 1132, or 1232. In some embodiments, a peripheral portion of the cover member that is adjacent the first portion of the cover member may have a stress pattern similar to that of the peripheral portion 1337 (e.g., when the peripheral portion 1337 extends around a periphery of the cover member). The exterior surface 1342 and the interior surface 1344 of the cover member 1330 are also shown in FIG. 13.

Although each of the symmetric stress patterns of the peripheral portion 1337 and the portion 1332 include compressive regions at the interior and the exterior surface of the cover member, the peripheral compressive regions 1387 of the peripheral portion 1337 are different from the compressive regions 1382 of the portion 1332. As shown in the example of FIG. 13, the depth D₁₃₇ of the peripheral compressive regions 1387 is greater than the depth D₁₃₂ of the compressive regions 1382. The increased depth D₁₃₇ of the peripheral compressive regions 1387 may provide increased protection against damage to the peripheral portion 1337 as compared to the portion 1332. The tensile regions 1392 and 1397 are also shown in FIG. 13.

The peripheral compressive regions 1387 may also differ from the compressive regions 1382 with respect to one or more of surface compressive stress values, maximum central tension values, composition, and the general shape of the compressive stress profile. In some examples, the surface compressive stress value of the peripheral compressive regions 1387 is greater than or equal to the surface compressive stress value of the compressive regions 1382. The greater surface compressive stress value of the peripheral compressive regions 1387 may be achieved by additional ion exchange within the peripheral portion. In other examples, the surface compressive stress value of the peripheral compressive regions 1387 is less than or equal to the surface compressive stress value of the compressive regions 1382. This combination of increased depth and reduced compressive stress of the compressive regions 1387 may be achieved by an annealing process, as described with respect to FIG. 15B.

FIG. 14A shows an example of compressive stress profiles in a hinge of a strengthened cover member. The compressive stress profiles 1493a and 1493b shown in FIG. 14A may be examples of compressive stress profiles through the thinnest part of the hinge, such as the third portion 733 of the cover member 730 of FIG. 7. As shown in FIG. 14A, the compressive stress varies through the thickness of the cover member T₁₄ at the hinge. The example of FIG. 14A is not intended to be limiting and in other examples the compressive stress as a function of distance in the hinge may vary as described below. The compressive stress profile at a thicker part of the cover member (e.g., at thickness T_{T}), may be different than the compressive stress profile in the hinge, as shown in the examples of FIGS. 15A and 18.

As shown in the example of FIG. 14A, the strengthened cover member defines a compressive region 1483a extending from an exterior surface of the cover member and a compressive region 1483b extending from an interior surface of the cover member. As shown in FIG. 14A, the compressive regions 1483a and 1483b are substantially symmetric at the exterior and the interior surfaces of the cover member (at a distance of zero and a distance equal to the thickness T₁₄). The compressive regions (1483a, 1483b) each have a depth D₁₄ₐ and a surface compressive stress CS₁₄. As shown in FIG. 14A, at least a portion of the compressive stress profiles 1493a, 1493b have a slope that is approximately constant. The example of FIG. 14A illustrates a compressive stress maximum at the exterior and the interior surfaces of the cover member. However, this example is not intended to be limiting and in other examples the maximum compressive stress may be offset with respect to the exterior and the interior surfaces of the cover member. In some embodiments, the maximum compressive stress may be greater than or equal to 600 MPa or 700 MPa and less than or equal to 1200 MPa, 1000 MPa, or 800 MPa. The hinge of the strengthened cover member typically also includes a tensile region 1463 positioned between the compressive stress region 1483a and 1483b. The tensile region 1463 defines a tensile stress profile 1473.

FIG. 14B shows an example of ion concentration as a function of distance in a hinge of a strengthened cover member. The ion concentrations shown in FIG. 14B may be an example of the ion concentrations in the compressive regions of FIG. 14A. Alternately or additionally, FIG. 14B may show an example of the variation in ion concentration through the third portion 733 of the cover member 730 of FIG. 7. As shown in FIG. 14B, the ion concentration varies through the thickness T₁₄ of the cover member at the hinge. The example of FIG. 14B is not intended to be limiting and in other examples the ion concentration as a function of distance in the hinge may vary as described below. The variation in ion concentration at a thicker part of the cover member (e.g., at thickness T_{T}), may be different than the variation in ion concentration in the hinge, as shown in the examples of FIGS. 15B and 15C.

As shown in the example of FIG. 14B, the strengthened cover member defines an ion-exchanged layer 1487a extending from an exterior surface of the cover member (alternately referred to as an exterior ion-exchanged layer or as a front ion-exchanged layer) and an ion-exchanged layer 1487b extending from an interior surface of the cover member (alternately referred to as an interior ion-exchanged layer or as a rear ion-exchanged layer). As shown in FIG. 14B, the ion exchange is substantially symmetric at the exterior and interior surfaces of the cover member (at a distance of zero and a distance equal to the thickness T₁₄). The ion-exchanged layers (1487a, 1487b) each have a depth D_{14b}.

Each of the ion exchanged layers 1487a and 1487b defines a respective ion concentration profile 1497a and 1497b. The cover member has an ion concentration C₁₄ at each of the exterior and the interior surfaces, which is a maximum ion concentration of the ions in this concentration profile. The ion concentration decreases with increasing distance from each surface. In the example of FIG. 14B, the ion concentration profiles 1497a and 1497b are approximately linear, with a slope that is approximately constant. The ion concentration profiles shown in FIG. 14B are exemplary rather than limiting and in other examples the ion concentration profiles may have a substantially constant slope over a relatively large portion of the profile or may have a slope that is not substantially constant. Alternately or additionally, if the as-formed composition of the glass includes some of the ions that are being introduced by ion exchange, the ion concentration at the depth D_{14b} may be non-zero.

The ion concentration profiles shown in FIG. 14B may result from the introduction of a single type of ion into the cover member through ion exchange. In some cases, the ion concentration profiles of FIG. 14B may result from the introduction of potassium ions into an ion-exchangeable material comprising sodium ions or lithium ions. The region of the cover member between the ion-exchanged layer 1487a, 1487b may be free of ions introduced by ion exchange and thus may have a composition that is the same as the as-formed composition of the cover member.

In some embodiments, the ion concentration profiles 1497a, 1497b of FIG. 14B create compressive regions extending from the exterior and the interior surfaces of the cover member and a tensile region positioned between the compressive regions. The resulting stress pattern may be similar to that shown in the third portion 1033 of the cover member 1030 of the example of FIG. 10. The compressive stress profile in the compressive regions may largely follow the ion concentration profile. Therefore, the ion concentration profiles 1497a, 1497b of FIG. 14B may produce an approximately constant slope of all or part of the compressive stress profile, as previously discussed with respect to FIG. 14A. However, the depth of the compressive regions may be different (e.g., less than) the depth of the ion-exchanged layer.

FIG. 15A shows an example of compressive stress profiles at a location outside the hinge of a strengthened cover member. The compressive stress profiles 1591a and1591b and the compressive regions 1581a and 1581b shown in FIG. 15A differ from the compressive stress profiles 1593a and 1593b and the compressive regions 1583a and 1583b shown in FIG. 14A, as described in more detail below. The compressive stress profiles 1591a and 1591b shown in FIG. 15A may be examples of compressive stress profiles in the first portion 731 or the second portion 732 of the cover member 730 of FIG. 7. As shown in FIG. 15A, the compressive stress varies through the thickness of the cover member. The example of FIG. 15A is not intended to be limiting and in other examples the compressive stress as a function of distance in the hinge may vary as described below.

As shown in the example of FIG. 15A, the strengthened cover member defines a compressive region 1581a extending from an exterior surface of the cover member and a compressive region 1581b extending from an interior surface of the cover member. The compressive regions (1581a, 1581b) each have a depth D₁₅ₐ and a surface compressive stress CS₁₅. As shown in FIG. 15A, the compressive regions 1581a and 1581b are substantially symmetric at the exterior and interior surfaces of the cover member (at a distance of zero and a distance equal to the thickness T₁₅). As shown in FIG. 15A, at least a portion of the compressive stress profiles 1591a, 1591b have a slope that is approximately constant. The example of FIG. 15A illustrates a compressive stress maximum at the exterior and the interior surfaces of the cover member. However, this example is not intended to be limiting and in other examples the maximum compressive stress may be offset with respect to the exterior and the interior surfaces of the cover member. A location outside the hinge of the strengthened cover member typically also includes a tensile region positioned between the compressive stress regions, examples of which were previously illustrated with respect to FIGS. 10 and 14A.

The compressive regions 1581a, 1581b shown in FIG. 15A differ from the compressive regions 1483a, 1483b shown in FIG. 14A. For example, the depth D₁₅ₐ is greater than the depth D₁₄ₐ. The surface compressive stress CS₁₅ shown in FIG. 15A is similar to the surface compressive stress CS₁₄ shown in FIG. 14A. However, in other examples, the surface compressive stress or maximum compressive stress at a location outside the hinge may be less than a surface or maximum compressive stress within the hinge.

FIG. 15B shows an example of ion concentration as a function of distance at a location outside the hinge of a strengthened cover member. The ion-exchanged layers 1586a, 1586b shown in FIG. 15B differ from the ion-exchanged layers 1487a, 1487b shown in FIG. 14B, as described in more detail below. The ion concentrations shown in FIG. 15B may be an example of the ion concentrations in the compressive regions of FIG. 15A. Alternately or additionally, FIG. 15B may show an example of the variation in ion concentration through the first portion 731 or the second portion 732 of the cover member 730 of FIG. 7. As shown in FIG. 15B, the ion concentration varies through the thickness of the cover member. The example of FIG. 15B is not intended to be limiting and in other examples the ion concentration as a function of distance in the hinge may vary as described below.

As shown in the example of FIG. 15B, the strengthened cover member defines an ion-exchanged layer 1586a extending from an exterior surface of the cover member and an ion-exchanged layer 1586b extending from an interior surface of the cover member. As shown in FIG. 15B, the ion exchange is substantially symmetric at the exterior and interior surfaces of the cover member (at a distance of zero and a distance equal to the thickness T₁₅). The ion-exchanged layers 1586a, 1586b each have a depth D_{15b}. The depth D_{15b} is greater than the depth D_{14b} of FIG. 14B due to the greater thickness Tis of this portion of the cover member.

Each of the ion exchanged layers 1586a and 1586b defines a respective ion concentration profile 1596a and 1596b. The cover member has an ion concentration C_{15b} at each of the exterior and the interior surfaces (at a distance of zero and a distance equal to the thickness T₁₅), which is a maximum ion concentration of the ions in this concentration profile. The ion concentration decreases with increasing distance from each surface. In the example of FIG. 15A, the ion concentration profiles 1596a and 1596b are approximately linear, with a slope that is approximately constant. The slope of each of the ion concentration profiles 1596a and 1596b is less than the slope of each of the ion concentration profiles 1497a and 1497b. The ion concentration profiles shown in FIG. 15B are exemplary rather than limiting and in other examples may vary in a similar way as described with respect to FIG. 14B.

In the example of FIG. 15B, the ion concentration C₁₅ at each of the exterior and the interior surfaces is about the same as the ion concentration C₁₄ at each of the exterior and the interior surfaces in the hinge. However, this example is not limiting and in other examples the ion concentration C_{15b} at the exterior and the interior surfaces may be less than the ion concentration C₁₄ at the exterior and the interior surfaces in the hinge (as shown in the example of FIG. 15C) or greater than the ion concentration C₁₄.

In some embodiments, the ion concentration profiles 1596a, 1596b of FIG. 15B create compressive regions extending from the exterior and the interior surfaces of the cover member and a tensile region positioned between the compressive regions. The resulting stress pattern may be similar to that shown in the first portion 1031 of the cover member 1030 in the example of FIG. 10. The compressive stress profile in the compressive regions may largely follow the ion concentration profile. Therefore, the ion concentration profiles 1596a, 1596b of FIG. 15A may produce an approximately constant slope of all or part of the compressive stress profile, as previously discussed with respect to FIG. 15A. However, the depth of the compressive regions may be less than the depth of the ion-exchanged layer.

FIG. 15C shows another example of ion concentration as a function of distance at a location outside the hinge of a strengthened cover member. The ion-exchanged layers 1588a, 1588b shown in FIG. 15C differ from the ion-exchanged layers 1586a, 1586b shown in FIG. 15B and the ion-exchanged layers 1487a, 1487b shown in FIG. 14B, as described in more detail below. FIG. 15C may show an example of the variation in ion concentration through the first portion 731 or the second portion 732 of the cover member 730 of FIG. 7. As shown in FIG. 15C, the ion concentration varies through the thickness of the cover member.

As shown in the example of FIG. 15C, the strengthened cover member defines an ion-exchanged layer 1588a extending from an exterior surface of the cover member and an ion-exchanged layer 1588b extending from an interior surface of the cover member. In the example of FIG. 15C, the ion exchange is substantially symmetric at the exterior and interior surfaces of the cover member (at a distance of zero and a distance equal to the thickness T₁₅). The ion-exchanged layers 1588a, 1588b each have a depth D_{15c}. The depth D_{15c} is greater than the depth D_{14b} of FIG. 14B and the depth D_{15b} of FIG. 15B.

Each of the ion exchanged layers 1588a and 1588b defines a respective ion concentration profile 1598a and 1598b. The cover member has an ion concentration Cise at each of the exterior and the interior surfaces (at a distance of zero and a distance equal to the thickness T₁₅), which is a maximum ion concentration of the ions in this concentration profile. The ion concentration decreases with increasing distance from each surface. In the example of FIG. 15C, the ion concentration profiles 1598a and 1598b are approximately linear, with a slope that is approximately constant. The ion concentration profiles shown in FIG. 15C are exemplary rather than limiting and in other examples may vary in a similar way as described with respect to FIG. 14B.

The ion concentration profiles 1598a and 1598b of FIG. 15C differ from those of FIGS. 14B and 15B in several respects. For example, the ion concentration profiles of FIG. 15C have a smaller slope than the ion concentration profiles of FIGS. 14B and 15B. Specifically, the slope of each of the ion concentration profiles 1598a and 1598b is less than the slope of each of the ion concentration profiles 1497a, 1497b, 1591a and 1591b. In addition, the ion concentration C_{15c} at each of the exterior and the interior surfaces shown in the example of FIG. 15C is less than the ion concentrations C₁₄ and C_{15b} of FIGS. 14B and 15B. In some examples, the ion concentration profiles of FIG. 15C may be obtained by locally annealing the cover member after conducting an ion exchange operation (e.g., locally annealing the first portion 731 and/or the second portion 732 of the cover member 730 of FIG. 7).

In a similar fashion as previously discussed with respect to FIG. 15B, the ion concentration profile of FIG. 15C creates compressive regions extending from the exterior and the interior surfaces of the cover member and a tensile region positioned between the compressive regions. The compressive stress profile in the compressive regions may largely follow the ion concentration profile. Therefore, in the example of FIG. 15C at least a portion of the compressive stress profile may have a slope that is approximately constant. However, the depth of the compressive regions may be less than the depth of the ion-exchanged layer. In contrast to the examples of FIG. 14B and FIG. 15B, the lower ion concentration C₁₅ₑ typically results in lower surface compressive surface stress.

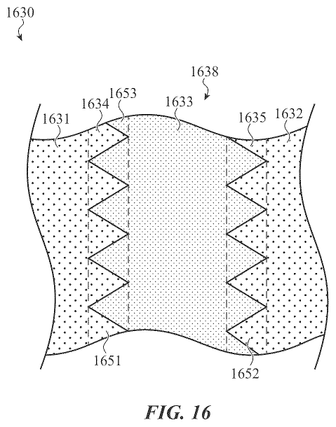

FIG. 16 shows another example of a strengthened cover member defining a hinge. The cover member 1630 has been strengthened to form at least one surface compressive region in each of a first portion 1631, a second portion 1632, a third portion 1633, a first intermediate portion 1634, and a second intermediate portion 1635. The third portion 1633 may have a thickness that is less than a thickness of each of the first portion 1631 and the second portion 1632. Furthermore, the third portion 1633, the first intermediate portion 1634, and the second intermediate portion 1635 may together define a hinge 1638 of the cover member, in a similar fashion as previously described with respect to FIG. 7.

In some embodiments, different portions of the cover member 1630 may have different stress patterns and ion exchange patterns, as generally indicated by the different levels of shading in FIG. 16. In the example of FIG. 16, the stress patterns within the third portion 1633 differ from those in the first portion 1631 and the second portion 1632. Furthermore, the stress patterns in the first intermediate portion 1634 and the second intermediate portion 1635 alternate to define a design.

In the example of FIG. 16, regions 1653 of the first intermediate portion 1634 and the second intermediate portion 1635 may have a stress pattern that is the same as a stress pattern of the third portion 1633. Regions 1651 of the first intermediate portion 1634 have a stress pattern that is the same as a stress pattern of the first portion 1631 and regions 1652 of the second intermediate portion have a stress pattern that is the same as a stress pattern of the second portion portion 1632. The shapes and sizes of the regions 1651 and 1653 of the first intermediate portion 1634 may be configured to produce an average in-plane expansion value that is matched to the in-plane expansion value of the third portion 1633 and the first portion 1631. The shapes and sizes of the regions 1652 and 1653 of the second intermediate portion 1635 may be configured to produce an average in-plane expansion value that is matched to the in-plane expansion value of the third portion 1633 and the second portion 1632.

The example of the alternating stress patterns in the first intermediate portion 1634 and the second intermediate portion 1635 of the cover member 1630 shown in FIG. 16 is exemplary rather than limiting. In other example, the shapes and sizes of the differently strengthened regions of the first intermediate portion and the second intermediate portion of the cover member may be changed to provide the desired values of in-plane expansion values in these portions of the cover member. The first portion 1631, the second portion 1632, the third portion 1633, the first intermediate portion 1634, and the second intermediate portion 1635 of the cover member 1630 may be similar in composition and dimensions to the first portion 731, the second portion 732, the third portion 733, the first intermediate portion 734, and the second intermediate portion 735 of the cover member 730.

The stress patterns in the first portion 1631, the second portion 1632, and the third portion 1633 of the cover member 1630 may be similar to stress patterns described in more detail with respect to other figures herein. For example, the stress pattern in the third portion 1633 may be similar to any of the stress patterns in hinges described herein, including the stress patterns and compressive stress profiles described with respect to FIGS. 7, 9, 10-12, and 14A. The stress patterns in the first portion 1631 and the second portion 1632 may be similar to any of the stress patterns outside the hinge described herein, including the stress patterns and compressive stress profiles described with respect to FIGS. 7, 9, 10-12, 15B, 15C, and 17-19.

Furthermore, the relationships between the ion exchange patterns in the first portion 1631, the second portion 1632, the third portion 1633, the first intermediate portion 1634, and the second intermediate portion 1635 of the cover member 1630 may be similar to those described for the stress patterns. For example, the regions 1653 of the first intermediate portion 1634 and the second intermediate portion 1635 may have an ion exchange pattern that is the same as an ion exchange pattern of the third portion 1633. Regions 1651 of the first intermediate portion 1634 may have an ion exchange pattern that is the same as a stress pattern of the first portion 1631 and regions 1652 of the second intermediate portion have an ion exchange pattern that is the same as an ion exchange pattern of the second portion 1632. The ion exchange patterns in the first portion 1631, the second portion 1632, and the third portion 1633 of the cover member 1630 may be similar to ion exchange patterns described in more detail with respect to other figures herein, including the ion exchange patterns and the ion concentration profiles described with respect to FIGS. 9, 10, and 15B.

As previously discussed, the cover member may include or be formed from a material capable of dual ion exchange. In some embodiments described herein, one or more portions of the hinge are strengthened through single ion exchange while other portions of the cover member are strengthened through dual ion exchange. These embodiments can allow deeper compressive regions to be formed in portions of the cover member away from the hinge and therefore provide additional damage protection for the cover member without creating undue tensile stress levels and/or mismatch of in-plane expansion values. FIGS. 17, 18, and 19 describe some examples of strengthening one or more portions of a cover member using a combination of single ion exchange and dual ion exchange. In additional examples, dual ion exchange may be used to strengthen the first and the second portions of the cover member, and optionally the first and the second intermediate portions of the cover member, of any of the examples of FIG. 10 through 13 or other cover members described herein.

FIG. 17 shows another cross-sectional view of a strengthened cover member. In the example of FIG. 17, the strengthened cover member 1730 defines a hinge that is strengthened differently than other portions of the cover member. In contrast to the examples of FIGS. 7-8 and 10-12, the hinge 1738 has a thickness that is substantially the same as another portion of the cover member 1730. In some embodiments, the thickness of the cover member 1730 is substantially uniform.

In the example of FIG. 17, a third symmetric stress pattern of a third portion 1733 of the cover member that defines a hinge 1738 is different from the first symmetric stress pattern of the first portion 1731 and the second symmetric stress pattern of the second portion 1732. Each of the first, second, and third symmetric stress patterns include compressive regions at the interior surface 1744 and the exterior surface 1742 of the cover member. However, the third compressive regions 1783 of the third portion 1733 are different from each of the first compressive regions 1781 of the first portion 1731 and the second compressive regions 1782 of the second portion 1732. As shown in the example of FIG. 17, the depth D₁₇₃ of the third compressive regions 1783 is less than the depth D₁₇₁ of the first compressive regions 1781 and the depth D₁₇₂ of the second compressive regions 1782. Limiting the depth D₁₇₃ of the third compressive regions 1783 may help limit both the average in-plane expansion value and the maximum central tension within the third portion 1733 of the cover member 1730. The increased depth D₁₇₁ of the first compressive regions 1781 and D₁₇₂ of the second compressive regions 1782 can help improve the damage resistance of the first portion 1731 and the second portion 1732 of the cover member 1730.

In some embodiments, the first compressive regions 1781 and the second compressive regions 1782 differ in composition from the third compressive regions 1783. The differences in composition of the first compressive regions 1781 and the second compressive regions 1782 as compared to the third compressive regions 1783 may result from differences in the ion exchange in the first portion 1731 and the second portion 1732 as compared to the third portion 1733 of the cover member. In some cases, the ion-exchanged layer in the third portion 1733 may be formed by single ion exchange while the ion exchanged layers formed in the first portion 1731 and the second portion 1732 may be formed by dual ion exchange. For example, a single type of ion (e.g., sodium) may be exchanged for smaller ions (e.g., lithium) present in the third portion 1733 and two different types of ions (e.g., sodium, potassium) may be exchanged for smaller ions present in the first portion 1731 and the second portion 1732 of the cover member 1730. The tensile regions 1791, 1792, and 1793 are also shown in FIG. 17.

As previously discussed, the compressive stress profile formed by introduction of two different types of ions may have a general shape that is different from the general shape of a compressive stress profile formed by introduction of a single type of ion into the cover member. When the first compressive regions 1781 and 1782 are formed by dual ion exchange and the compressive region 1782 is formed by single ion exchanges, the general shape of the compressive stress profiles in the first compressive regions 1781 and the second compressive regions 1782 may differ from the general shape of the compressive stress profiles in the third compressive regions 1783. In some examples, the compressive stress profiles in the third compressive regions 1783 may be similar to those previously discussed with respect to FIG. 14A. However, the compressive stress profiles in the first and the second compressive regions 1781, 1782 may be similar to those discussed with respect to FIG. 18. The discussion provided with respect to FIG. 18 is generally applicable herein and is not repeated here.

Each of the first portion 1731, the second portion 1732, and the third portion 1733 of the cover member 1730 may comprise respective ion-exchanged layers that define respective ion concentration profiles, as previously discussed with respect to FIGS. 9 and 10. In some embodiments, the composition of the ion-exchanged layers in the third portion 1733 may be different from the composition of the ion-exchanged layers of the first portion 1731 and the second portion 1732. As a result, the composition of the compressive regions 1783 may differ from the composition of the compressive regions 1781 and 1782.

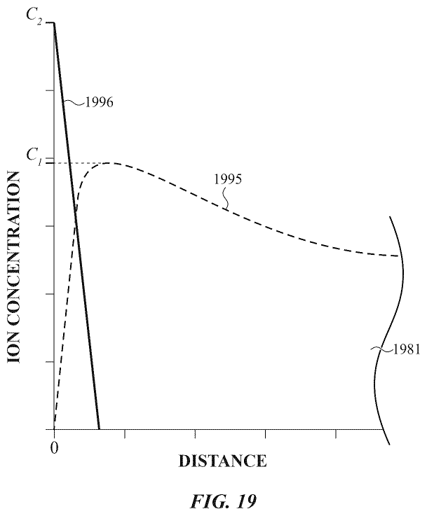

The ion concentration profiles in the third portion 1733 may be different from the ion concentration profiles of the first portion 1731 and the second portion 1732. In some embodiments, the ion concentration profiles in the third portion 1733 may be similar to those shown in FIG. 14B. The ion concentration profiles in the first portion 1731 and the second portion 1732 may be similar to those described with respect to FIG. 19.

FIG. 18 shows an example of a compressive stress profile at location outside the hinge of a strengthened cover member. The compressive stress profile 1891 may be present within a compressive region 1881 of the strengthened cover member. The compressive stress profile 1891 of FIG. 18 may be formed by introduction of two different types of ions into a cover member by ion exchange with smaller ions present in the cover member. As shown in FIG. 18, the compressive stress varies through the thickness of the cover member. A location outside the hinge of the strengthened cover member typically also includes a tensile region positioned between the compressive stress regions, examples of which were previously illustrated with respect to FIGS. 10 and 14A.

The compressive stress profile 1891 of FIG. 18 has a surface compressive stress CS₁₈ and a depth of compression D₁₈. The compressive stress profile 1891 also defines an inflection point 1875 (which may be alternately referred to as a “knee” or as a slope transition) at a compressive stress CSK and a depth DK. The inflection point 1875 divides the compressive stress profile 1891 into a first portion 1891a that extends from the surface of the cover member to the slope inflection point 1875 and a second portion 1891b that extends from the inflection point 1875 to the depth of compression D₁₈. The compressive region 1881 may also be described as having a first portion 1881a that extends from the surface of the cover member to the location of the slope inflection point 1875 and a second portion 1881b that extends from the location of the inflection point 1875 to the depth of compression D₁₈. As shown in the example of FIG. 18, the cover member is symmetrically strengthened. In some examples, a compressive stress profile having a shape similar to the compressive stress profile 1891 may produce a tensile stress profile within the tensile region that is different from the tensile stress profile produced by compressive stress profiles having a shape similar to the compressive stress profiles shown in FIG. 15A. In some cases, the maximum tensile stress in the tensile region may be reduced as compared to the example of FIG. 15A.

The first portion 1881a may alternately be referred to herein as a surface portion of the compressive region and the second portion 1881b may alternately be referred to herein as a core portion of the compressive region. The first portion 1881a may be enriched with potassium ions as compared to the second portion 1881b as described in more detail with respect to FIG. 19. The discussion provided with respect to FIG. 19 is generally applicable herein and is not repeated here.

FIG. 19 shows examples of ion concentration profiles within an ion exchanged layer of a strengthened cover member. The ion concentration profiles 1995 and 1995 may be present within the ion exchanged layer 1981 of the strengthened cover member. The ion concentration profiles 1995 and 1996 may be examples of ion concentration profiles resulting from dual ion exchange. For convenience of illustration, only a portion of the ion exchange profile 1995 and the ion-exchanged layer 1981 is shown in FIG. 19. The cover member may be symmetrically ion-exchanged, having similar ion-exchanged layers at the exterior and interior surfaces.

In the example of FIG. 19, the ion concentration profile 1995 represents the concentration of a first type of ion (e.g., sodium ions) as a function of distance and the ion concentration profile 1996 represents the concentration of a second type of ion (e.g., potassium ions) as a function of distance. The vertical axis in FIG. 19 represents a surface of the cover member, such as the exterior surface or the interior surface. The size of the second type of ions is larger than the size of the first type of ions, so that ions of the second type do not extend as far into the cover member as the ions of the first type. Therefore, the ions of the second type are concentrated in a surface region of the cover member.

The ion profile 1995 increases from a low value at the surface of the cover member to a maximum value C₁ before decreasing again. When the ion concentration profile 1995 represents a concentration of sodium ions, the concentration C₁ is a maximum concentration of sodium ions. The depth of the ion-exchanged layer is determined by the ion concentration profile 1995.

The ion concentration profile 1996 has a maximum concentration C₂ of the second kind of ions at the surface of the cover member and decreases with increasing distance from the surface of the cover member. When the ion concentration profile 1996 represents a concentration of potassium ions, the concentration C₂ is a maximum concentration of potassium ions. In the example of FIG. 19, the slope of the ion concentration profile 1996 is approximately constant. The ion concentration profiles shown in FIG. 19 are exemplary rather than limiting and in other examples ion concentrations profiles obtained by dual ion exchange may vary from those shown in FIG. 19. For example, the maximum potassium concentration may be located inward from the surface, the maximum potassium concentration value and location may vary, and the slopes of the ion concentration profiles may vary from those illustrated in FIG. 19.

FIG. 20 shows an example block diagram of components of an electronic device. The electronic device 2000 can incorporate an enclosure having a strengthened cover as described herein. The schematic representation of FIG. 20 may correspond to components of the devices depicted in FIGS. 1, 2A, 2B, 3, 4A-4B, and 5 as described above. However, FIG. 20 may also more generally represent other types of electronic devices including an enclosure having a strengthened cover as described herein.

In embodiments, an electronic device 2000 may include a display 2002. The display 2002 may include a liquid-crystal display (LCD), a light-emitting diode (LED) display, an LED-backlit LCD display, an organic light-emitting diode (OLED) display, an active layer organic light-emitting diode (AMOLED) display, an organic electroluminescent (EL) display, an electrophoretic ink display, or the like. If the display 2002 is a liquid-crystal display or an electrophoretic ink display, the display 2002 may also include a backlight component that can be controlled to provide variable levels of display brightness. If the display 2002 is an organic light-emitting diode or an organic electroluminescent-type display, the brightness of the display 2002 may be controlled by modifying the electrical signals that are provided to display elements. In addition, information regarding configuration and/or orientation of the electronic device may be used to control the output of the display as described with respect to input devices 2012. In some cases, the display is integrated with a touch and/or force sensor in order to detect touches and/or forces applied along an exterior surface of the device 2000.

The device 2000 also includes a processor 2004. The processor 2004 may be operably connected with a computer-readable memory 2008. The processor 2004 may be operatively connected to the memory 2008 component via an electronic bus or bridge. The processor 2004 may be implemented as one or more computer processors or microcontrollers configured to perform operations in response to computer-readable instructions. The processor 2004 may include a central processing unit (CPU) of the device 2000. Additionally, and/or alternatively, the processor 2004 may include other electronic circuitry within the device 2000 including application specific integrated chips (ASIC) and other microcontroller devices. The processor 2004 may be configured to perform functionality described in the examples above.

The device 2000 also includes a power source 2006. In some embodiments, the power source includes a battery that is configured to provide electrical power to the components of the electronic device 2000. The battery may include one or more power storage cells that are linked together to provide an internal supply of electrical power. The battery may be operatively coupled to power management circuitry that is configured to provide appropriate voltage and power levels for individual components or groups of components within the electronic device 2000. The battery, via power management circuitry, may be configured to receive power from an external source, such as an alternating current power outlet. The battery may store received power so that the electronic device 2000 may operate without connection to an external power source for an extended period of time, which may range from several hours to several days.

The memory 2008 may include a variety of types of non-transitory computer-readable storage media, including, for example, read access memory (RAM), read-only memory (ROM), erasable programmable memory (e.g., EPROM and EEPROM), or flash memory. The memory 2008 is configured to store computer-readable instructions, sensor values, and other persistent software elements.

The device 2000 also includes a sensor system 2010. The sensor system 2010 may include one or more sensors or sensor components, such as a force sensor, a capacitive sensor, an accelerometer, a barometer, a gyroscope, a proximity sensor, a light sensor, a microphone, an acoustic sensor, a light sensor (including ambient light, infrared (IR) light, ultraviolet (UV) light), an optical facial recognition sensor, a depth measuring sensor (e.g., a time of flight sensor), a health monitoring sensor (e.g., an electrocardiogram (erg) sensor, a heart rate sensor, a photoplethysmogram (ppg) sensor, a pulse oximeter, a biometric sensor (e.g., a fingerprint sensor), or other types of sensing device. In some cases, the device 2000 includes a sensor array (also referred to as a sensing array) which includes multiple sensors. For example, a sensor array may include an ambient light sensor, a Lidar sensor, and a microphone. In additional examples, one or more camera components may also be associated with the sensor array. The sensor system 2010 may be operably coupled to processing circuitry. In some embodiments, the sensors may detect deformation and/or changes in configuration of the electronic device and be operably coupled to processing circuitry that controls the display based on the sensor signals. In some implementations, output from the sensor system is used to reconfigure the display output to correspond to an orientation or folded/unfolded configuration or state of the device. Example sensors for this purpose include accelerometers, gyroscopes, magnetometers, and other similar types of position/orientation sensing devices.

The input/output mechanism 2012 may include one or more input devices and one or more output devices. The input device(s) are devices that are configured to receive input from a user or the environment. An input device may include, for example, a push button, a touch-activated button, a capacitive touch sensor, a touch screen (e.g., a touch-sensitive display or a force-sensitive display), a capacitive touch button, dial, crown, or the like. In some embodiments, an input device may provide a dedicated or primary function, including, for example, a power button, volume buttons, home buttons, scroll wheels, and camera buttons. The one or more output devices include the display 2002 that renders visual information, which may be generated by the processor 2004. The one or more output devices may also include one or more speakers to provide audio output and/or one or more haptic devices that are configured to produce a haptic or tactile output along an exterior surface of the device 2000. The input/output mechanism may also include a communication port or a communication channel. A communication channel may include one or more wireless interface(s) that are adapted to provide communication between the processor 2004 and an external device, one or more antennas (e.g., antennas that include or use housing components as radiating members), communications circuitry, firmware, software, or any other components or systems that facilitate wireless communications with other devices.

The electronic device 2000 also includes a system 2014 in communication with the elements 2002, 2004, 2006, 2008, 2010, and 2012. In some examples, the system 2014 includes circuitry, such as electronic buses and/or bridges. The system 2014 may also include application specific integrated chips (ASIC) and other microcontroller devices.

As used herein, use of the term “about” with references to similarity of two values may signify a variation of +/−5% or less between the two values. Furthermore, use of the term “substantially” or “approximately” with respect to similarity of two values, elements, or alignment of elements may signify a variation of +/−5% or less.

The following discussion applies to the electronic devices described herein to the extent that these devices may be used to obtain personally identifiable information data. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An electronic device comprising:
a display assembly;
a housing at least partially enclosing the display assembly; and
a cover coupled to the housing and defining a first window positioned over a first portion of the display assembly, a second window positioned over a second portion of the display assembly, and a hinge structure positioned between the first and the second windows, the cover including a cover member formed from a glass material and comprising:
a first portion at least partially defining the first window and having:
a first thickness; and
a first stress pattern defining a first compressive region depth and a first in-plane expansion value;
a second portion at least partially defining the second window and having:
a second thickness; and
a second stress pattern defining a second compressive region depth and a second in-plane expansion value; and
a hinge portion positioned between the first and the second portions and at least partially defining the hinge structure, an unfolded configuration of the hinge portion having:
a third thickness that is less than a thickness of each of the first thickness and the second thickness; and
a third stress pattern that is different from each of the first and the second stress patterns, the third stress pattern defining:
a third compressive region depth that is greater than zero and less than each of the first compressive region depth and the second compressive region depth; and
a third in-plane expansion value that is matched to each of the first in-plane expansion value and the second in-plane expansion value.

2. The electronic device of claim 1, wherein:
the hinge portion defines a bend in a folded configuration of the cover member;
the first stress pattern is symmetric through the first thickness;
the second stress pattern is symmetric through the second thickness; and
the third stress pattern is symmetric through the third thickness.

3. The electronic device of claim 2, wherein:
the bend defines a bend radius from 1 mm to 10 mm in the folded configuration of the cover; and
the third thickness is in a range from 20 micrometers to 120 micrometers.

4. The electronic device of claim 2, wherein:
the hinge portion of the cover member further comprises:
a third portion of the cover member that defines the third thickness;
a first intermediate portion that is integrally formed with the first portion and the third portion, the first intermediate portion having a thickness that transitions from the first thickness to the third thickness and defining a fourth stress pattern that is different from each of the first stress pattern and the third stress pattern;
a second intermediate portion that is integrally formed with the second portion and the third portion, the second intermediate portion having a thickness that transitions from the second thickness to the third thickness and defining a fifth stress pattern that is different from each of the second stress pattern and the third stress pattern;
a rear surface of the third portion, a rear surface of the first intermediate portion, and a rear surface of the second intermediate portion together define a recess; and
the display assembly is coupled to the rear surfaces of of the third portion, the first intermediate portion, and the second intermediate portion of the cover member.

5. The electronic device of claim 4, wherein:
a fourth in-plane expansion value of the first intermediate portion is matched to the third in-plane expansion value; and
a fifth in-plane expansion value of the second intermediate portion is matched to the third in-plane expansion value.

6. The electronic device of claim 4, wherein:
the cover member further comprises a multilayer coupling structure positioned between the cover member and the display assembly; and
the multilayer coupling structure defines:
a first thickness below each of the first and the second portions of the cover member; and
a second thickness within the recess that is greater than the first thickness.

7. The electronic device of claim 1, wherein an exterior surface of the hinge portion of the cover member has an out of plane displacement of 0.75 micrometers or less in the unfolded configuration of the cover.

8. An electronic device comprising:
a display assembly comprising a first active display area, a second active display area, and a third active display area;
a housing at least partially enclosing the display assembly; and
a cover coupled to the housing and comprising a cover member formed from a glass material and configured to move between a folded configuration and an unfolded configuration, the cover member comprising:
a first portion positioned over the first active display area and defining:
a first thickness; and
a first stress pattern having a first surface compressive stress and a first compressive region depth at an interior surface of the cover member;
a second portion positioned over the second active display area and defining:
a second thickness; and
a second stress pattern having a second surface compressive stress and a second compressive region depth at the interior surface; and
a third portion positioned between the first portion and the second portion and over the third active display area, the third portion defining a bend in the folded configuration of the cover member and defining, in the unfolded configuration of the cover member:
a third thickness that is less than each of the first thickness and the second thickness; and
a third stress pattern that is different from each of the first and the second stress patterns, the third stress pattern having:
a third compressive region depth that is less than or equal to each of the first compressive region depth and the second compressive region depth at the interior surface; and
a third surface compressive stress that is greater than or equal to each of the first surface compressive stress and the second surface compressive stress at the interior surface of the cover member.

9. The electronic device of claim 8, wherein:
the display assembly further comprises a touch-sensitive layer comprising:
a first region in the first portion of the display assembly; and
a second region in the second portion of the display assembly; and
the display assembly is configured to allow independent control of the first region and the second region of the touch-sensitive layer.

10. The electronic device of claim 9, wherein:
the first active display area is configured to display a keyboard in at least one mode of operation; and
the first region of the touch-sensitive layer is configured to receive input to keys of the keyboard.

11. The electronic device of claim 9, wherein the third surface compressive stress is greater than each of the first surface compressive stress and the second surface compressive stress at the interior surface of the cover member in the unfolded configuration of the cover member.

12. The electronic device of claim 9, wherein:
a ratio of the third compressive region depth to the third thickness is matched to a ratio of the first compressive region depth to the first thickness; and
the ratio of the third compressive region depth to the third thickness is matched to a ratio of the second compressive region depth to the second thickness.

13. The electronic device of claim 9, wherein:
the first portion of the cover member has a first maximum tension value;
the second portion of the cover member has a second maximum tension value; and
the third portion of the cover member has a third maximum tension value that is greater than each of the first maximum tension value and the second maximum tension value.

14. The electronic device of claim 9, wherein
the cover member further comprises a first intermediate portion positioned between the first portion and the third portion, the first intermediate portion defining a fourth width that is less than a third width of the third portion; and
the cover member further comprises a second intermediate portion positioned between the second portion and the third portion, the second intermediate portion defining a fifth width that is less than the third width of the third portion.

15. An electronic device comprising:
a display assembly comprising a touch-sensitive layer;
a housing at least partially enclosing the display assembly; and
a cover coupled to the housing and positioned over the display assembly, the cover including a cover member comprising:
a first portion positioned over a first portion of the display assembly, the first portion of the cover member having:
a first thickness; and
a first rear ion-exchanged layer having a first depth;
a second portion positioned over a second portion of the display assembly, the second portion of the cover member having:
a second thickness; and
a second rear ion-exchanged layer having a second depth;
a third portion positioned between the first and the second portions and over a third portion of the display assembly, the third portion of the cover member having:
a third thickness less than each of the first and the second thicknesses; and
a third rear ion-exchanged layer having a third depth less than each of the first depth of the first rear ion-exchanged layer and the second depth of the second rear ion-exchanged layer;
a first intermediate portion positioned between the third portion and the first portion and defining a fourth rear ion-exchanged layer; and
a second intermediate portion positioned between the third portion and the second portion and defining a fifth rear ion-exchanged layer.

16. The electronic device of claim 15, wherein:
the first intermediate portion has a thickness that transitions from the first thickness to the third thickness;
the fourth rear ion-exchanged layer has a depth that is in a range from the first depth to the third depth;
the second intermediate portion has a thickness that transitions from the second thickness to the third thickness; and
the fifth rear ion-exchanged layer has a depth that is in a range from the second depth to the third depth.

17. The electronic device of claim 16, wherein:
the depth of the fourth rear ion-exchanged layer varies with the thickness of the first intermediate portion; and
the depth of the fifth rear ion-exchanged layer varies with the thickness of the second intermediate portion.

18. The electronic device of claim 16, wherein, in an unfolded configuration of the cover member, the third rear ion-exchanged layer defines a third surface compressive stress that is greater than each of a first surface compressive stress defined by the first rear ion-exchanged layer and a second surface compressive stress defined by the second rear ion-exchanged layer.

19. The electronic device of claim 16, wherein:
the second portion of the cover member further defines a second front ion-exchanged layer extending from a front surface of the cover member;
a peripheral portion of the cover member defines a sixth front ion-exchanged layer extending from the front surface of the cover member; and
a depth of the sixth front ion-exchanged layer is greater than a depth of the second front ion-exchanged layer.

20. The electronic device of claim 15, further comprising:
a first set of polymer layers positioned between the cover member and a front of the display assembly and configured to allow relative movement between the cover member and the display assembly;
a flexible plate coupled to a rear of the display assembly, and
a second set of polymer layers positioned between the display assembly and the flexible plate and configured to allow relative movement between the display assembly and the flexible plate.
